(19) United States
(12) Patent Application Publication
(10) Pub. No.: US 2016/0163663 A1
(43) Pub. Date: Jun. 9, 2016

(54) SEMICONDUCTOR LIGHT-EMITTING DEVICE AND SEMICONDUCTOR LIGHT-EMITTING APPARATUS HAVING THE SAME

(71) Applicant: Samsung Electronics Co., Ltd., Suwon-si (KR)

(72) Inventors: Gi-bum KIM, Yongin-si (KR); Sang-hyun LEE, Suwon-si (KR); Ho-seob LEE, Yongin-si (KR)

(21) Appl. No.: 14/958,922

(22) Filed: Dec. 3, 2015

(30) Foreign Application Priority Data
Dec. 3, 2014 (KR) 10-2014-0172458

(51) Int. Cl. H01L 23/00

(52) U.S. Cl. CPC H01L 24/05; H01L 24/13; H01L 2224/0401; H01L 2224/05023; H01L 2224/0508; H01L 2224/05099; H01L 2224/13026; H01L 2924/12041; H01L 2924/014

(57) ABSTRACT

An embodiment includes a semiconductor light-emitting device comprising: an electrode pad; a first under-barrier metal (UBM) layer stacked on the electrode pad; a second UBM layer stacked on the first UBM layer and having a multilayered structure including at least two layers; and a solder bump disposed on the second UBM layer, wherein adhesion between the second UBM layer and the first UBM layer is higher than adhesion between the first UBM layer and the solder bump.

### CROSS-REFERENCE TO RELATED APPLICATION

This application claims the benefit of Korean Patent Application No. 10-2014-0172458, filed on Dec. 3, 2014, in the Korean Intellectual Property Office, the disclosure of which is incorporated herein in its entirety by reference.

### BACKGROUND

Embodiments relate to a semiconductor light-emitting device and a semiconductor light-emitting apparatus including the same, and more particularly, to a semiconductor light-emitting device and a semiconductor light-emitting apparatus including the same, which may improve adhesion to solder bumps and increase reliability.

A flip-chip bonding technique may be a method of mounting a semiconductor chip on a substrate by using a solder bump formed on an electrode pad. The flip-chip bonding technique may be effectively applied to an electrode pad having a finer pitch than a wire bonding technique of electrically connecting an electrode pad with an internal lead by using a wire. The solder bump may be formed by plating the electrode pad with a solder and reflowing the solder. The solder bump may be formed on an under-barrier metal (UBM) layer. The UBM layer may have a multilayered structure including an adhesive layer, a diffusion barrier layer, and a wetting layer. However, a metal oxide layer generated during a process of forming the solder bump may inhibit formation of an intermetallic compound between the solder bump and the wetting layer, thereby causing separation of the solder bump.

### SUMMARY

An embodiment includes a semiconductor light-emitting device comprising: an electrode pad; a first under-barrier metal (UBM) layer stacked on the electrode pad; a second UBM layer stacked on the first UBM layer and having a multilayered structure including at least two layers; and a solder bump disposed on the second UBM layer, wherein adhesion between the second UBM layer and the first UBM layer is higher than adhesion between the first UBM layer and the solder bump.

An embodiment includes a semiconductor light-emitting apparatus comprising a solder bump, the apparatus comprising: an electric circuit; a first under-barrier metal (UBM) layer configured to electrically connect the solder bump with an electrode pad that is connected to the electric circuit; and a second UBM layer stacked on the first UBM layer and configured to increase adhesion of the first UBM layer with the solder bump.

An embodiment includes a semiconductor light-emitting device comprising: an electrode pad; a first adhesive layer stacked on the electrode pad; a diffusion barrier layer stacked on the first adhesive layer; a first wetting layer stacked on the diffusion barrier layer; a second adhesive layer stacked on the first wetting layer; a third adhesive layer stacked on the second adhesive layer; a second wetting layer stacked on the third adhesive layer; and a solder bump formed on the second wetting layer.

### BRIEF DESCRIPTION OF THE DRAWINGS

Embodiments will be more clearly understood from the following detailed description taken in conjunction with the accompanying drawings in which:

FIG. 1A is a schematic plan view of a semiconductor light-emitting device according to an embodiment;

FIG. 1B is a side cross-sectional view of the semiconductor light-emitting device, which is taken along a line A-A′ of FIG. 1A, according to an embodiment;

FIG. 1C is a partial enlarged view of a solder pad unit of a semiconductor chip of FIG. 1B;

FIGS. 2A-2D are side cross-sectional views of a structure of a first under-barrier metal (UBM) layer, according to various embodiments;

FIGS. 3A and 3B are side cross-sectional views of a structure of a second UBM layer, according to various embodiments;

FIGS. 4A and 4B are detailed side cross-sectional views of a stacked structure of a solder pad unit, according to various embodiments;

FIG. 5 is a side cross-sectional view of a solder pad unit according to another embodiment;

FIG. 6 is a diagram of a stacked shape of a second UBM layer according to an embodiment;

FIG. 7 is a detailed diagram of a stacked structure of a solder pad unit according to another embodiment;

FIGS. 8A, 8B, and 8C are flowcharts of a method of manufacturing a solder pad unit according to an embodiment;

FIGS. 9A to 9E illustrate a method of manufacturing a solder pad unit according to an embodiment;

FIG. 10 is an exploded perspective view of a backlight (BL) assembly including a light-emitting device array unit in which an LED chip manufactured using a method of manufacturing an LED chip, according to an embodiment, is arranged;

FIG. 11 is a schematic diagram of a flat-panel semiconductor light-emitting apparatus including a light-emitting device array unit and a light-emitting device module in which an LED chip manufactured using a method of manufacturing an LED chip, according to an embodiment, is arranged;

FIG. 12 is a schematic diagram of a bulb-type lamp, which is a semiconductor light-emitting apparatus including a light-emitting device array unit and a light-emitting device module in which an LED chip manufactured using a method of manufacturing an LED chip, according to an embodiment, is arranged;

FIG. 13 is an international commission on illumination (CIE) chromaticity diagram of a complete radiator spectrum;

FIGS. 14A and B are each a diagram of an example of a light-emitting device package in which an LED chip manufactured using a method of manufacturing an LED chip, according to an embodiment, is arranged;

FIGS. 15 and 16 are examples of light-emitting device packages according to various embodiments;

FIG. 17 is a diagram of a lamp that includes a light-emitting device array unit and a light-emitting device module in which an LED chip manufactured using a method of manufacturing an LED chip, according to an embodiment, is arranged, and includes a communication module;

FIG. 18 is a diagram of an example in which a lamp including a light-emitting device array unit and a light-emitting device module in which an LED chip manufactured using a method of manufacturing an LED chip, according to an embodiment, is arranged, is applied to a home-network;

FIG. 19 is a cross-sectional view of an example of a package to which a semiconductor light-emitting device according to an embodiment is applied; and

FIGS. 20 and 21 are cross-sectional views of various examples of an LED chip 7110, which may be applied to a light source module, according to an embodiment.

### DETAILED DESCRIPTION OF THE EMBODIMENTS

Embodiments will now be described more fully hereinafter with reference to the accompanying drawings, in which particular embodiments are shown. These embodiments are provided so that this disclosure is thorough and complete and fully conveys the scope to one skilled in the art. Accordingly, embodiments can be modified in various ways and take on various alternative forms, specific embodiments thereof are shown in the drawings and described in detail below as examples. There is no intent to limit embodiments to the particular forms disclosed. On the contrary, embodiments cover all modifications, equivalents, and alternatives falling within the spirit and scope. Like reference numerals refer to like elements throughout. In the drawings, the thicknesses of layers and regions may be exaggerated for clarity.

The terminology used herein is for the purpose of describing particular embodiments only and is not intended to be limiting of all embodiments. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the inventive concept.

Unless otherwise defined, all terms (including technical and scientific terms) used herein have the same meaning as commonly understood by one of normal skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “and/or” includes any and all combinations of one or more of the associated listed items. Expressions such as “at least one of,” when preceding a list of elements, modify the entire list of elements and do not modify the individual elements of the list.

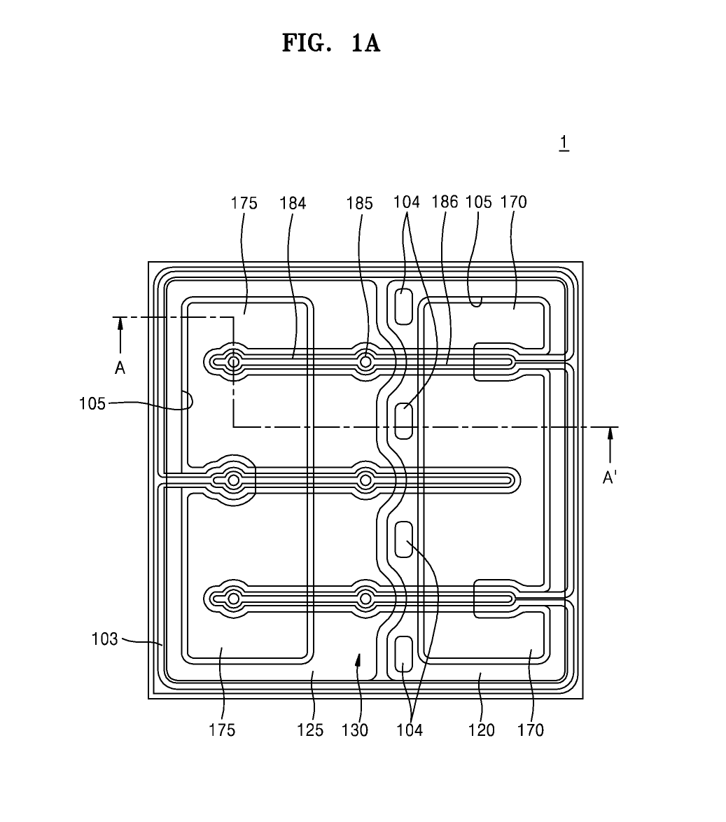

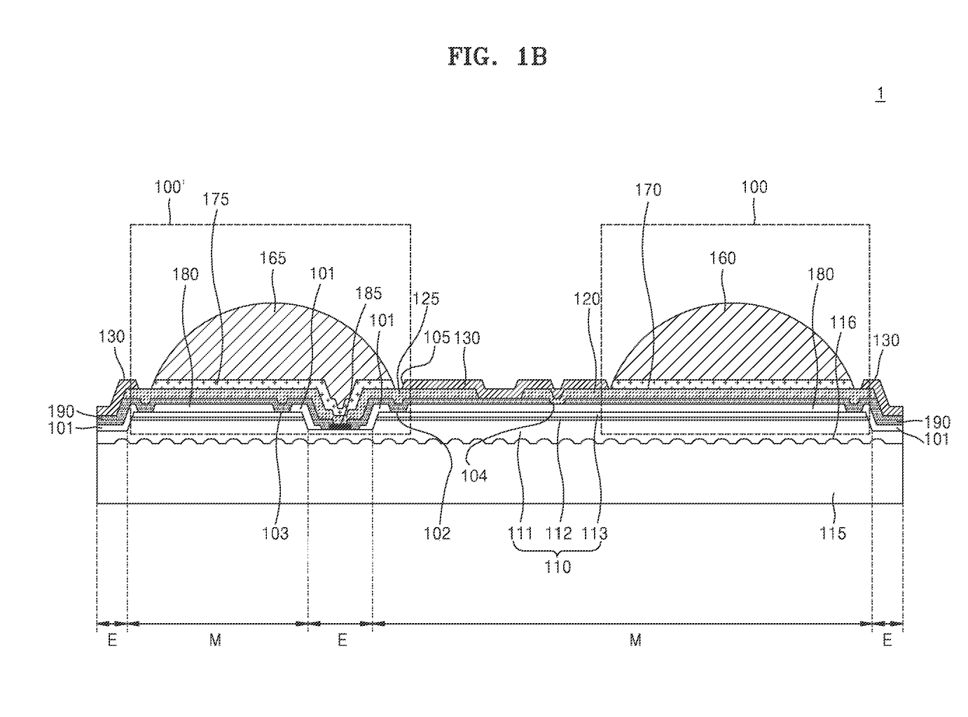

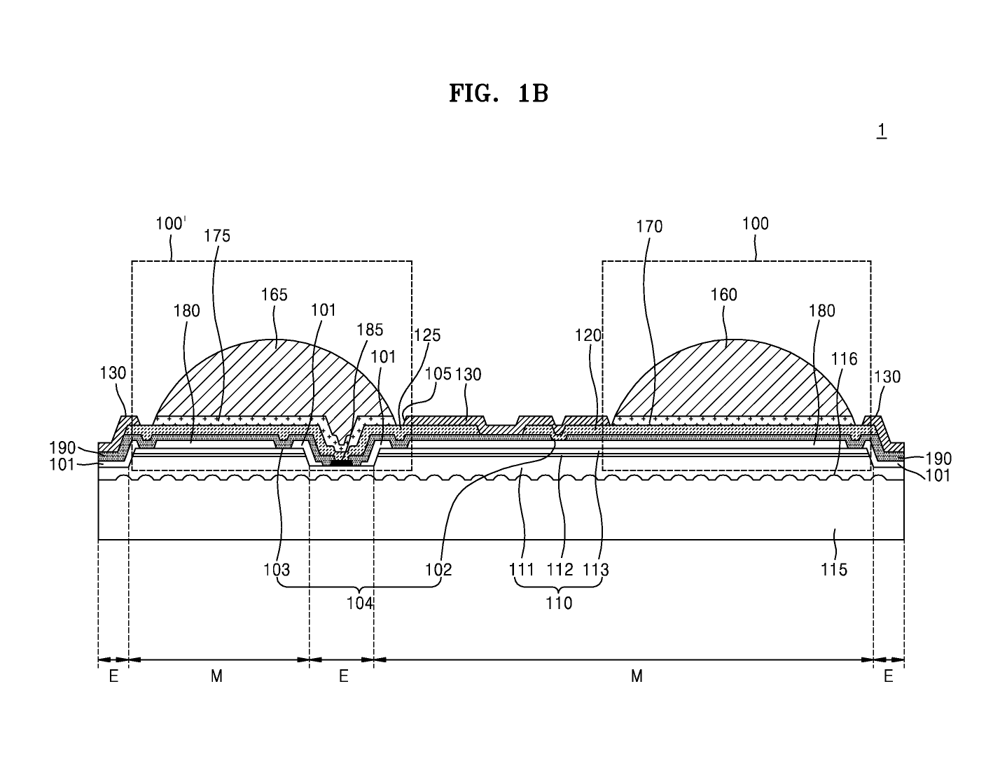

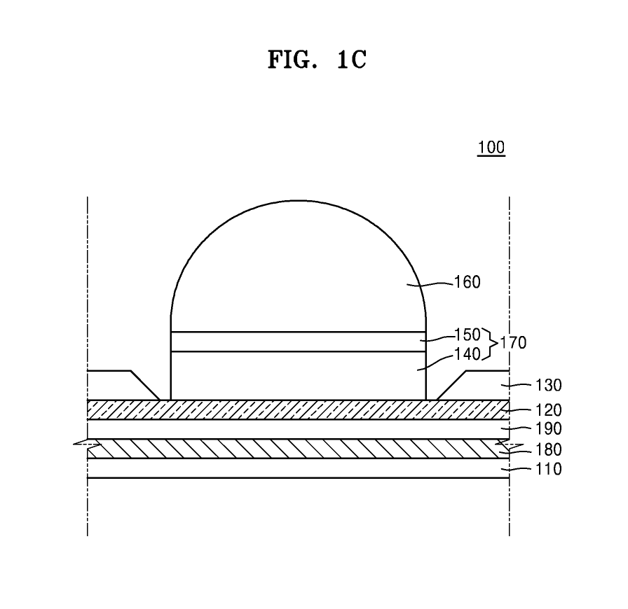

FIG. 1A is a schematic plan view of a semiconductor light-emitting device 1 according to an embodiment. FIG. 1B is a side cross-sectional view of the semiconductor light-emitting device 1, which is taken along a line A-A′ of FIG. 1A, according to an embodiment. FIG. 1C is a partial enlarged view of a solder pad unit 100 of a semiconductor chip of FIG. 1B.

The semiconductor light-emitting device 1 may include solder pad units 100 and 100′. The semiconductor light-emitting device 1 may have a stacked structure of multiple semiconductor layers. A semiconductor layer 110 may be stacked on a substrate 115. The semiconductor layer 110 may include a first-conductivity-type semiconductor layer 111, an active layer 112, and a second-conductivity-type semiconductor layer 113.

The substrate 115 may include a semiconductor growth substrate and may be formed using insulating, conductive, and semiconductor materials, such as sapphire, Si, SiC, MgAl₂O₄, MgO, LiAlO₂, LiGaO₂, GaN, or the like. A sapphire substrate, which is widely used as a nitride semiconductor growth substrate, may be formed of a crystal having an electrical insulation characteristic and a Hexa-Rhombo R3c symmetry. The sapphire substrate may have a lattice constant of about 13.001 Å along a C-axis and a lattice constant of about 4.758 Å along an A-axis and have a C(0001) plane, an A(11-20) plane, and an R(1-102) plane. In this case, since the C plane may be used to relatively easily grow a thin nitride layer that may be stable at high temperatures, the sapphire substrate may be mainly used as a nitride growth substrate.

In addition, as shown in FIG. 1B, multiple rough structures 116 may be formed on a top surface of the substrate 115 on which semiconductor layers are grown. The crystallinity and light emission efficiency of the semiconductor layers may be improved due to the rough structures 116. Although the present embodiment describes an example in which each of the rough structures 116 has a convex dome-like shape, embodiments are not limited thereto. For example, each of the rough structures 116 may have one of various shapes, such as a square shape or a triangular shape. In other embodiments, the rough structures 116 may be omitted.

The substrate 115 may be sequentially removed in some embodiments. That is, the substrate 115 may be provided as a growth substrate for growing the first-conductivity-type semiconductor layer 111, the active layer 112, and the second-conductivity-type semiconductor layer 113 and removed by using a separation process. The substrate 115 may be separated from the semiconductor layer 110 by using a laser lift-off (LLO) process, a chemical lift-off (CLO) process, or the like.

Although not shown, a buffer layer may be further provided on a top surface of the substrate 115. The buffer layer may serve to reduce lattice defects of a semiconductor layer grown on the substrate 115. The buffer layer may include an undoped semiconductor layer formed of nitride. For example, the buffer layer may reduce a difference in lattice constant between the substrate 115 formed of sapphire and the first-conductivity-type semiconductor layer 111 formed of gallium nitride (GaN) stacked on the top surface of the substrate 115 and increase crystallinity of the first-conductivity-type semiconductor layer 111 formed of GaN. The buffer layer may be formed by growing undoped GaN, AlN, InGaN, or the like to a thickness of about several tens of Å to several hundred Å at a low temperature of about 500° C. to about 600° C. Here, an undoped semiconductor layer refers to a semiconductor layer on which an additional impurity doping process is not performed. When impurities (e.g., GaN) inherently contained in the semiconductor layer are grown using a metal organic chemical vapor deposition (MOCVD) process, silicon (Si) used as a dopant may be unintentionally contained in the semiconductor layer at a dose of about 10¹⁴ ions/cm³ to about 10¹⁸ ions/cm³. In some embodiments, the buffer layer may be omitted.

The first-conductivity-type semiconductor layer 111 stacked on the substrate 115 may include an n-type doped semiconductor such as an n-type nitride semiconductor layer. Also, the second-conductivity-type semiconductor layer 113 may include a p-type doped semiconductor, such as a p-type nitride semiconductor layer. However, in some embodiments, the first and second-conductivity-type semiconductor layers 111 and 113 may be switched. Each of the first and second-conductivity-type semiconductor layers 111 and 113 may be formed of a material expressed by formula: AlₓIn_{y}Ga_{(1-x-y)}N (here, 0≦x<1, 0≦y<1, 0≦x+y<1), for example, GaN, AlGaN, InGaN, or AlInGaN. The first and second-conductivity-type semiconductor layers 111 and 113 may, but need not include the same material.

The active layer 112 disposed between the first- and second-conductivity-type semiconductor layers 111 and 113 may be configured to emit light having predetermined energy due to re-combination between electrons and holes. The active layer 112 may include a material having a lower energy bandgap than energy bandgaps of the first- and second-conductivity-type semiconductor layers 111 and 113. For example, when the first- and second-conductivity-type semiconductor layers 111 and 113 include a GaN-based compound semiconductor, the active layer 112 may include an InGaN-based compound semiconductor having a lower energy bandgap than an energy bandgap of GaN. Also, the active layer 112 may have a multiple quantum well (MQW) structure (e.g., an InGaN/GaN structure) formed by alternately stacking quantum well layers and quantum barrier layers. However, embodiments are not limited thereto, and the active layer 112 may have a single quantum well (SQW) structure.

As shown in FIG. 1B, the semiconductor light-emitting device 1 may include an etching region E formed by etching portions of the second-conductivity-type semiconductor layer 113, the active layer 112, and the first-conductivity-type semiconductor layer 111 and multiple mesa regions M at least partially partitioned by the etching region E.

From a top view, the etching region E may have a gap structure that is cut from one side surface of the semiconductor light-emitting device 1 having a rectangular shape toward another side surface thereof, which is an opposite side surface, to have a predetermined thickness and a predetermined length. Also, multiple etching regions E may be arranged parallel to one another within a rectangular region of the semiconductor light-emitting device 1. Accordingly, at least some of the etching regions E may be surrounded with the mesa regions M.

A first contact electrode 184 may be disposed on a top surface of the first-conductivity-type semiconductor layer 111, which is exposed by the etching region E, and connected to the first-conductivity-type semiconductor layer 111. A second contact electrode 180 may be disposed on top surfaces of the plurality of mesa regions M and connected to the second-conductivity-type semiconductor layer 113. The first and second contact electrodes 184 and 180 may be disposed on a first surface of the semiconductor light-emitting device 1. Accordingly, the first and second contact electrodes 184 and 180 may be disposed on the same surface of the semiconductor light-emitting device 1 so that the semiconductor light-emitting device 1 may be mounted on a package main body using a flip-chip bonding technique.

As shown in FIG. 1A, the first contact electrode 184 may include multiple pad units 185 and multiple finger units 186, which may have a smaller width than the pad units 185 and extend from the pad units 185, respectively. The first contact electrode 184 may extend along the etching region E. Also, multiple first contact electrodes 184 may be arranged a predetermined distance apart from one another and generally uniformly distributed on the first-conductivity-type semiconductor layer 111. Accordingly, current supplied through the first contact electrodes 184 into the first-conductivity-type semiconductor layer 111 may uniformly flow through substantially the entire first-conductivity-type semiconductor layer 111.

The pad units 185 may be disposed apart from one another, and the finger units 186 may be respectively connected to the pad units 185. The finger units 186 may respectively have different widths. For example, as in this embodiment, when the first contact electrode 184 has two finger units 186, one finger unit 186 may have a greater width than the other finger units 186. A width of the any one finger unit 186 may be controlled in consideration of a resistance of current supplied through the first contact electrode 184.

The second contact electrode 180 may include metal reflective layer. Also, the second contact electrode 180 may further include a metal coating layer to cover the metal reflective layer. However, the second contact electrode 180 may selectively include the metal coating layer, and may be omitted in some embodiments. The second contact electrode 180 may substantially cover a top surface of the second-conductivity-type semiconductor layer 113 in the mesa region M.

A first insulating layer 101 formed of an insulating material may be disposed on the semiconductor light-emitting device 1 including side surfaces of the mesa region M to cover the active layer 112 exposed by the etching region E. For example, the first insulating layer 101 may be formed of an insulating material including a material, such as SiO₂, SiN, SiOₓN_{y}, TiO₂, Si₃N₄, Al₂O₃, TiN, AlN, ZrO₂, TiAlN, TiSiN, or the like. Also, the first insulating layer 101 may include first and second openings 102 and 103 formed by exposing partial regions of the first and second-conductivity-type semiconductor layers 111 and 113, and the first and second contact electrodes 184 and 180 may be disposed in the first and second openings 102 and 103. The first insulating layer 101 may be configured to reduce a chance of or prevent an electrical short from occurring between the first and second contact electrodes 184 and 180 and the active layer 112 and reduce a chance of or prevent the first and second-conductivity-type semiconductor layers 111 and 113 from being electrically directly connected to each other.

A second insulating layer 190 may be provided on the semiconductor light-emitting device 1 to substantially cover the entire semiconductor light-emitting device 1. In an embodiment, the second insulating layer 190 may have a reflection structure to reflect light emitted by the active layer 112, except light traveling toward the substrate 115, and re-direct the reflected light toward the substrate 115. The second insulating layer 190 may have a multilayered structure formed by alternately stacking layers having different refractive indices. In general, a flip-chip-type semiconductor light-emitting device may allow light generated by the active layer 112 to be emitted in a direction in which the substrate 115 is disposed. A portion of light emitted in a direction in which the electrode pads 120 and 125 are disposed, which is opposite to the direction in which the substrate 115 is disposed, may be absorbed into a semiconductor layer or a metal layer and lost. The second insulating layer 190 may have a multilayered reflection structure, which is a reflection structure configured to redirect light traveling in a direction opposite of the substrate 115 toward the substrate 115.

The second insulating layer 190 may include multiple openings 104 respectively disposed over the first contact electrode 184 and the second contact electrode 180. Specifically, the openings 104 may be provided in positions corresponding respectively to the first contact electrode 184 and the second contact electrode 180 and partially expose the corresponding first contact electrode 184 and second contact electrode 180.

As shown in FIG. 1B, the electrode pads 120 and 125 may be partially insulated from the first and second-conductivity-type semiconductor layers 111 and 113 by the second insulating layer 190 that substantially covers the top surface of the semiconductor light-emitting device 1. Also, the electrode pads 120 and 125 may be connected to the first contact electrode 184 and the second contact electrode 180, which are partially exposed through the openings 104, and electrically connected to the first and second-conductivity-type semiconductor layers 111 and 113. The electrical connection of the electrode pads 120 and 125 with the first and second-conductivity-type semiconductor layers 111 and 113 may be variously controlled by the openings 104 formed in the second insulating layer 190.

At least a pair of electrode pads 120 and 125 including a first electrode pad 125 and a second electrode pad 120 may be provided. The first electrode pad 125 may be electrically connected to the first-conductivity-type semiconductor layer 111 through the first contact electrode 184, and the second electrode pad 120 may be electrically connected to the second-conductivity-type semiconductor layer 113 through the second contact electrode 180.

The electrode pads 120 and 125 may include, for example, a material including at least one of gold (Au), tungsten (W), platinum (Pt), silicon (Si), iridium (Ir), silver (Ag), copper (Cu), nickel (Ni), titanium (Ti), chromium (Cr), and an alloy thereof.

A passivation layer 130 may be provided on the electrode pads 120 and 125 and cover and protect the entire electrode pads 120 and 125. Also, the passivation layer 130 may include a bonding region 105 to partially expose the electrode pads 120 and 125. Multiple bonding regions 105 may be disposed to partially expose the first electrode pad 125 and the second electrode pad 120. In this case, some of the bonding regions 105 may be disposed not to overlap some of multiple openings 104 of the second insulating layer 190. For example, as shown in FIG. 1B, a bonding region, which partially exposes the second electrode pad 120 from among the bonding regions 105, may not overlap the opening 104, which partially exposes the second contact electrode 180 from among the openings 104. That is, the bonding region 105 may not be disposed over the opening 104 in a vertical direction. Also, the bonding region 105 that partially exposes the first electrode pad 125 may partially overlap the opening 104 that partially exposes the first contact electrode 184.

The present embodiment describes an example in which two bonding regions 105 are provided parallel to each other, but embodiments are not limited thereto. In other embodiments, the number and arrangement of the bonding regions 105 may be different. The passivation layer 130 may be formed of the same or similar material as the second insulating layer 190. Meanwhile, similar to the bonding region 105, the passivation layer 130 may further include an open region that partially exposes the first and second electrode pads 125 and 120. Before the semiconductor light-emitting device 1 is mounted, the opening may be provided as a region connected to a probe pin (not shown) so as to ascertain whether the semiconductor light-emitting device 1 operates.

The solder pads 170 and 175 may be respectively disposed on the bonding region 105. The solder pads 170 and 175 may include a first solder pad 175 and a second solder pad 170, and respectively connected to the first and second electrode pads 125 and 120 that are partially exposed through the bonding region 105. Also, the solder pads 170 and 175 may be electrically connected to the first-conductivity-type semiconductor layer 111 and the second-conductivity-type semiconductor layer 113 through the electrode pads 120 and 125. The solder pads 170 and 175 may include a material including at least one of nickel (Ni), gold (Au), copper (Cu), and an alloy thereof.

The present embodiment describes an example in which one first solder pad 175 and one second solder pad 170 are provided, but embodiments are not limited thereto. In other embodiments, the numbers and arrangements of the first solder pads 175 and the second solder pads 170 may be different. However, in some embodiments the first solder pad 175 and the second solder pad 170 may be adjusted to have substantially the same area. First and second solder bumps 165 and 160 may be respectively disposed on the first solder pad 175 and the second solder pad 170. The first and second solder pads 175 and 170 will be described in detail with reference to FIG. 1C.

FIG. 1C is an enlarged side cross-sectional view of the solder pad unit 100, which is a portion of a semiconductor chip of FIG. 1B, which includes the second solder bump 160, the second solder pad 170, the second electrode pad 120, the second insulating layer 190, the second contact electrode 180, the semiconductor layer 110, and the passivation layer 130. In FIG. 1C, the second insulating layer 190 of FIG. 1B may be referred to as an insulating layer 190, the second solder bump 160 of FIG. 1B may be referred to as a solder bump 160, the second solder pad 170 of FIG. 1B may be referred to as an UBM layer 170, and the second contact electrode 180 of FIG. 1B may be referred to as an electrode 180.

The solder pad unit 100 of FIG. 1C may include the solder bump 160, the UBM layer 170, the passivation layer 130, the insulating layer 190, the electrode 180, and the semiconductor layer 110. The UBM layer 170 may correspond to the second solder pad 170 of FIG. 1B and include a first UBM layer 140 and a second UBM layer 150.

The solder pad unit 100 may include the solder bump 160 for a flip-chip bonding technique. In an embodiment, the solder pad unit 100 may be a portion of an LED chip. The solder pad unit 100 may include the solder bump 160 that is appropriate for mounting the semiconductor chip. The solder pad unit 100 may include the semiconductor layer 110 configured to emit light, the electrode 180 electrically connected to the semiconductor layer 110, the electrode pad 120 electrically connected to the electrode 180, the insulating layer 190 configured to insulate a remaining portion other than a portion where the electrode 180 is connected to the electrode pad 120, the passivation layer 130 configured to insulate a remaining portion other than an exposed portion of the electrode pad 120, the solder bump 160 electrically connected to the electrode pad 120, and the first UBM layer 140 and the second UBM layer 150 configured to electrically connect and physically adhere the electrode pad 120 and the solder bump 160 and reduce a chance of or prevent separation of the solder bump 160.

The electrode pad 120 may include various conductive materials. In an embodiment, the electrode pad 120 may include at least one of copper (Cu), aluminum (Al), and an alloy thereof. The electrode pad 120 may be connected to electric circuits installed in the solder pad unit 100 through a conductive trace (not shown).

In an embodiment, the passivation layer 130 may include at least one of silicon nitride and silicon oxide. The passivation layer 130 may be formed by stacking silicon nitride or silicon oxide on the electrode pad 120. The passivation layer 130 may be etched to expose at least a portion of the electrode pad 120.

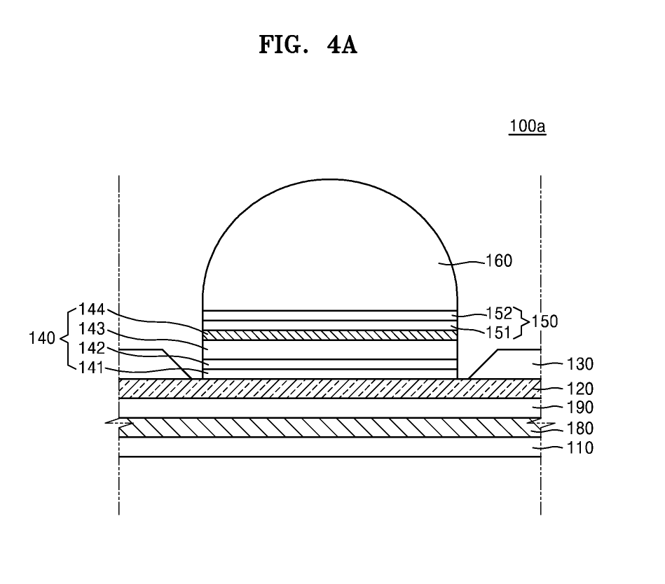

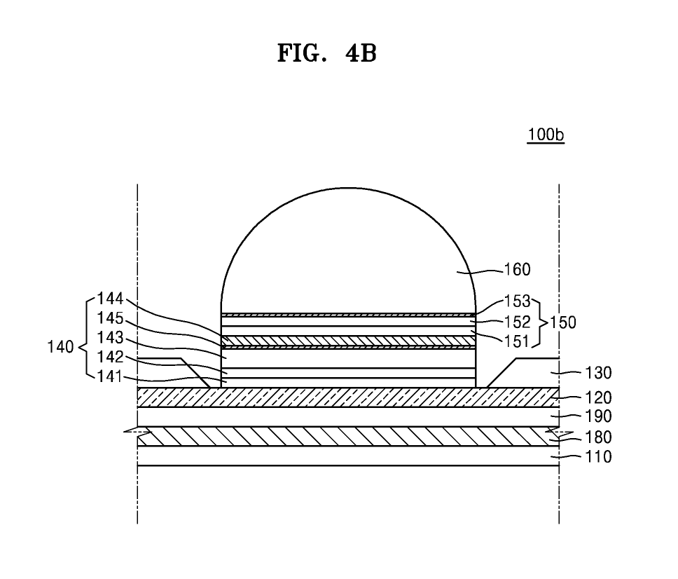

Referring to FIGS. 1C and 4A, the first UBM layer 140 may include a first adhesive layer 141 stacked on and adhered to the electrode pad 120. The first adhesive layer 141 may be formed on a portion of the passivation layer 130 and a portion of the electrode pad 120. According to an embodiment, the first adhesive layer 141 may include at least one material of titanium, nickel, and an alloy thereof. The first UBM layer 140 may include a diffusion barrier layer 142 stacked on the first adhesive layer 141. The diffusion barrier layer 142 may reduce a chance of or prevent a solder element of the solder bump 160 from diffusing into the first adhesive layer 141 or the electrode pad 120. The diffusion barrier layer 142 may include at least one of nickel (Ni) and molybdenum (Mo). In a particular example, the diffusion barrier layer 142 may include at least one of nickel (Ni) and 90% molybdenum (Mo). In an embodiment, the diffusion barrier layer 142 may include the same material as the first adhesive layer 141. Also, the first adhesive layer 141 and the diffusion barrier layer 142 may be simultaneously formed using one process or separately formed using different processes.

The first UBM layer 140 may include a first wetting layer 143 stacked on the diffusion barrier layer 142. The first wetting layer 143 may have a surface that may be easily combined with the solder of the solder bump 160. In other words, an intermetallic compound may be formed due to a reaction of a base material of the first wetting layer 143 with the solder. Furthermore, the first wetting layer 143 may further include a compound layer formed of an intermetallic compound. However, embodiments are not limited thereto, and the intermetallic compound may be distributed in the entire first wetting layer 143 or formed only in a portion of the first wetting layer 143. The first wetting layer 143 may include at least one of cobalt (Co), copper (Cu), gold (Au), nickel (Ni), silver (Ag), and an alloy thereof.

In addition, the first UBM layer 140 may include a second adhesive layer 144, which is stacked on the first wetting layer 143 and is more adhesive to an insulating layer than the first wetting layer 143. When an insulating layer is formed on the first UBM layer 140, the first UBM layer 140 may include the second adhesive layer 144 as an upper layer so that formation of voids between the first UBM layer 140 and the insulating layer may be reduced or prevented due to a high adhesion of the second adhesive layer 144 to the insulating layer. The second adhesive layer 144 may include at least one of a refractory metal (e.g., titanium, chromium, zinc, molybdenum, and tungsten), nickel, and an alloy thereof. However, embodiments are not limited thereto, and the second adhesive layer 144 may include various metal materials.

The second adhesive layer 144 may include an adhesive oxide layer formed by oxidizing a material contained in the second adhesive layer 144, which is exposed due to a process. In an embodiment, the adhesive oxide layer may be formed by oxidizing the entire second adhesive layer 144 or a portion of the second adhesive layer 144. However, embodiments are not limited thereto and the adhesive oxide layer may take various forms. When the second adhesive layer 144 contains titanium (Ti), the adhesive oxide layer may contain titanium oxide (TiO₂). A material of the adhesive oxide layer may vary according to the kind of a metal material contained in the second adhesive layer 144.

The second UBM layer 150 may be stacked on the first UBM layer 140. The first UBM layer 140 may have a different horizontal width from the second UBM layer 150. In an embodiment, the first UBM layer 140 may have a larger horizontal width than the second UBM layer 150, and detailed descriptions thereof will be presented later. Also, the second UBM layer 150 may be stacked in multiple pieces on the first UBM layer 140 by etching the insulating layer or patterning photoresist, as described in detail later.

The second UBM layer 150 may include a third adhesive layer 151, which is stacked on and adhered to the second adhesive layer 144 or the adhesive oxide layer, and a second wetting layer 152, which is disposed on the third adhesive layer 151 and may be more easily adhered to the solder bump 160. The third adhesive layer 151 may be selected such that adhesion of the third adhesive layer 151 to the second adhesive layer 144 or the adhesive oxide layer is higher than adhesion of the second wetting layer 152 to the second adhesive layer 144 or the adhesive oxide layer. Accordingly, the third adhesive layer 151 may include a material that may be more easily adhered to a material contained in the second adhesive layer 144 or the adhesive oxide layer. Since the second UBM layer 150 may include the third adhesive layer 151, the second UBM layer 150 may be adhered to the first UBM layer 140 with a higher adhesive strength. In an embodiment, the third adhesive layer 151 may be formed of the same material as the second adhesive layer 144. For example, when the second adhesive layer 144 includes titanium (Ti) and the adhesive oxide layer is formed of titanium oxide (TiO₂), the third adhesive layer 151 may include titanium. However, embodiments are not limited thereto, and the third adhesive layer 151 may include at least one of a refractory metal (e.g., titanium, chromium, zinc, molybdenum, and tungsten), nickel, and an alloy thereof, according to a metal contained in the second adhesive layer 144.

The second wetting layer 152 may have a surface that may be more easily combined with the solder of the solder bump 160. In other words, an intermetallic compound may be formed due to a reaction of a base material of the second wetting layer 152 with the solder. Furthermore, the second wetting layer 152 may further include a compound layer formed of the intermetallic compound. However, embodiments are not limited thereto, and the intermetallic compound may be distributed in the entire second wetting layer 152 or formed only in a portion of the second wetting layer 152. The second wetting layer 152 may include at least one of cobalt, copper, gold, nickel, silver, and an alloy thereof. Also, in an embodiment, the first wetting layer 143 of the first UBM layer 140 may include a different material from or the same material as the second wetting layer 152 of the second UBM layer 150.

The solder pad unit 100 may include the solder bump 160, which may be formed on the second UBM layer 150. A portion of the solder bump 160 may be formed on the first UBM layer 140 according to a stacked shape of the second UBM layer 150. For example, the solder bump 160 may include tin (Sn), tin/silver (Sn/Ag), tin/bismuth (Sn/Bi), tin/copper (Sn/Cu), tin/silver (Sn/Ag), tin/gold (Sn/Au), or tin/silver/copper (Sn/Si/Cu). Also, the solder bump 160 may contain tin, which may take up to 90% or more of the weight of the solder bump 160, and be formed using an electroplating process, a screen printing process, or the like.

As described above, the second UBM layer 150, which may be more adhesive to the solder bump 160 than the first UBM layer 140, may be stacked on the first UBM layer 140. Thus, the solder pad 170 may be adhered to the solder bump 160 more strongly than a conventional structure in which only the first UBM layer 140 is stacked, thereby increasing reliability of a chip or apparatus including the solder bump 160.

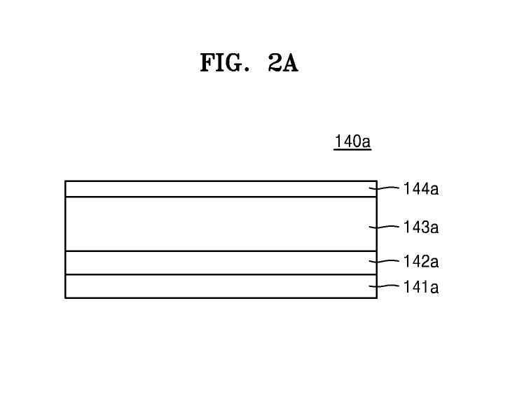

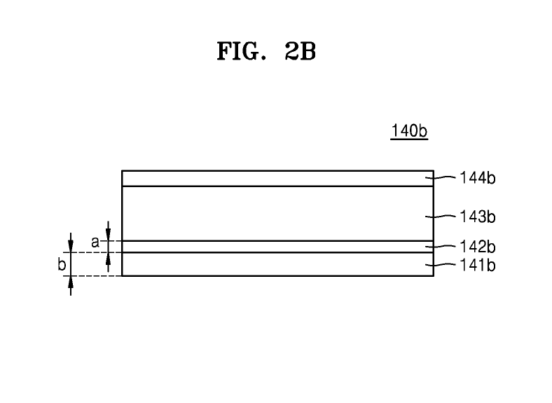

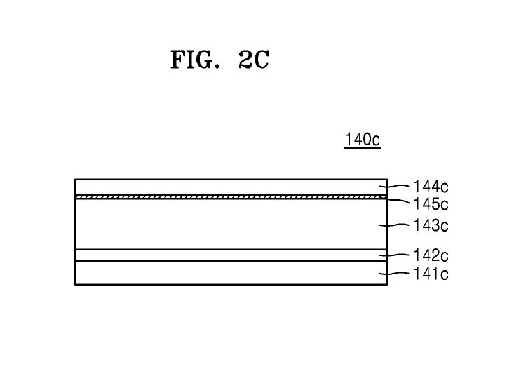

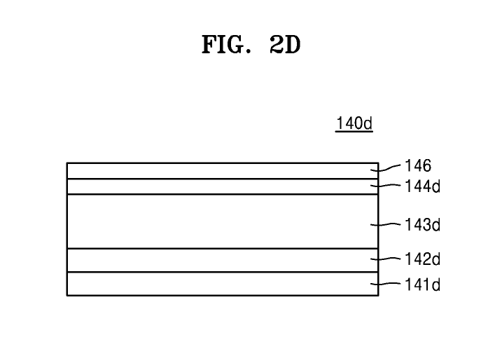

FIGS. 2A, 2B, and 2C are side cross-sectional views of a structure of the first UBM layer 140, according to various embodiments. Referring to FIG. 2A, a first UBM layer 140a may include a first adhesive layer 141a, a diffusion barrier layer 142a, a first wetting layer 143a, and a second adhesive layer 144a. The first adhesive layer 141a may be stacked on and adhered to an electrode pad 120 and formed on a portion of a passivation layer and a portion of the electrode pad 120. In an embodiment, the first adhesive layer 141a may include at least one material of titanium, nickel, and an alloy thereof.

The diffusion barrier layer 142a may be stacked on the first adhesive layer 141a and reduce a chance of or prevent a solder of a solder bump from diffusing to the electrode pad 120 or the first adhesive layer 141a and causing an intermetallic chemical reaction. The diffusion barrier layer 142a and the first adhesive layer 141a may be simultaneously formed using one process or separately formed using multiple or different processes. The diffusion barrier layer may include at least one of nickel and molybdenum, such as at least one of nickel and 90% molybdenum. In an embodiment, the diffusion barrier layer 142a may be formed of the same material as the first adhesive layer 141a.

The first wetting layer 143a may be stacked on the diffusion barrier layer 142a. The first wetting layer 143a may have a surface that may be more easily combined with the solder of the solder bump. That is, a first intermetallic compound may be formed due to a reaction of a base material of the first wetting layer 143a with the solder. Furthermore, the first wetting layer 143a may further include a first compound layer formed of the first intermetallic compound. However, embodiments are not limited thereto, and the first intermetallic compound may be distributed in the entire first wetting layer 143a or formed only in a portion of the first wetting layer 143a. The first wetting layer 143a may include at least one of cobalt, copper, gold, nickel, silver, and an alloy thereof.

To improve adhesion of the first UBM layer 140a with an insulating layer formed of an insulating material, such as silicon oxide or silicon nitride, the second adhesive layer 144a may be stacked on the first wetting layer 143a. The second adhesive layer 144a may include at least one of a refractory metal (e.g., titanium, chromium, zinc, molybdenum, and tungsten), nickel, and an alloy thereof. However, embodiments are not limited thereto, and the second adhesive layer 144a may include various metal materials. The second adhesive layer 144a may include an adhesive oxide layer formed by oxidizing a material contained in the second adhesive layer 144 that is exposed due to a process. At least a portion of the second adhesive layer 144a may include an adhesive oxide layer. In an embodiment, the adhesive oxide layer may be formed by oxidizing the entire second adhesive layer 144a. However, embodiments are not limited thereto, and the second adhesive layer 144a may be formed only on a portion of the first wetting layer 143a or may not be provided on the first wetting layer 143a.

Referring to FIG. 2B, a first UBM layer 140b may have a similar structure as the first UBM layer 140a of FIG. 2A, but a first adhesive layer 141b and a diffusion barrier layer 142b may be different from the first adhesive layer 141a and the diffusion barrier layer 142a of FIG. 2A. A height ‘b’ of the first adhesive layer 141b may be different from a height ‘a’ of the diffusion barrier layer 142b. Furthermore, the first adhesive layer 141b may be stacked to a greater height ‘b’ than the height ‘a’ of the diffusion barrier layer 142b. Also, the first adhesive layer 141b may include the same or similar material as the diffusion barrier layer 142b. In addition, the first adhesive layer 141b and the diffusion barrier layer 142b may be substantially simultaneously formed using one process or separately formed using different processes.

Referring to FIG. 2C, a first UBM layer 140c may have a structure similar to the first UBM layer 140a, but a first compound layer 145c may be formed of a first intermetallic compound on a first wetting layer 143c. The first compound layer 145c may include the first intermetallic compound, which is formed due to a chemical reaction of a solder of a solder bump with a base element of the first wetting layer 143c. Although FIG. 2C illustrates an example in which the first compound layer 145c is formed only on a top surface of the first wetting layer 143c, embodiments are not limited thereto. For example, the first compound layer 145c may be formed in a deep region of the first wetting layer 143c. Furthermore, the first compound layer 145c may be formed in the entire first wetting layer 143c and on a top surface of the diffusion barrier layer 142c.

Referring to FIG. 2D, a first UBM layer 140d may have a structure similar to the first UBM layer 140a. In this embodiment, an insulating layer 146 is illustrated stacked on the second adhesive layer 144d. The second adhesive layer 144d may have an adhesion to the insulating layer 146 that is higher than an adhesion of the first wetting layer 143d to the insulating layer 146.

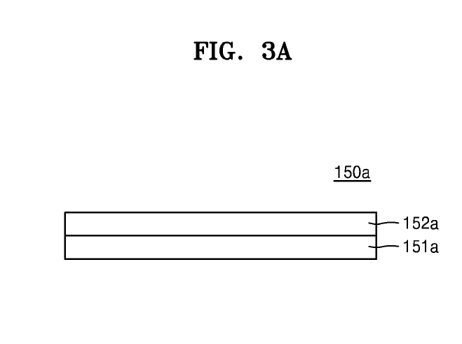

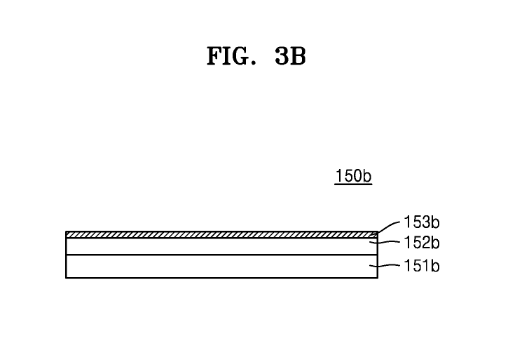

FIGS. 3A and 3B are side cross-sectional views of the second UBM layer 150, according to various embodiments. Referring to FIG. 3A, a second UBM layer 150a may include a third adhesive layer 151a and a second wetting layer 152a. The third adhesive layer 151a may be stacked on and adhered to an upper layer of the first UBM layer 140. The third adhesive layer 151a may be selected such that adhesion of the third adhesive layer 151a to the first UBM layer 140 is higher than adhesion of the second wetting layer 152a to the first UBM layer 140. Accordingly, the third adhesive layer 151a may include a material that may be more easily adhered to a material contained in the upper layer of the first UBM layer 140. A material of the third adhesive layer 151a may depend on the material contained in the upper layer of the first UBM layer 140. Since the second UBM layer 150a includes the third adhesive layer 151a, the second UBM layer 150a may be adhered to the first UBM layer 140 with a higher adhesive strength.

Referring to FIG. 3B, a second UBM layer 150b may further include a second compound layer 153b in contrast with the second UBM layer 150a of FIG. 3A. The second compound layer 153b may include a second intermetallic compound that is formed due to a chemical reaction of a solder of a solder bump with a base element of a second wetting layer 152b. FIG. 3B illustrates an example in which the second compound layer 153b is formed only on a top surface of the second wetting layer 152b, but embodiments are not limited thereto. For example, the second compound layer 153b may be formed in a deep region of the second wetting layer 152b. Also, the second compound layer 153b may be formed in the entire second wetting layer 152b. Furthermore, a third adhesive layer 151b may include a third intermetallic compound, which is formed due to a chemical reaction of a base material of the third adhesive layer 151b with the solder of the solder bump.

FIGS. 4A and 4B are detailed side cross-sectional views of stacked structures of solder pad units 100a and 100b according to various embodiments. Referring to FIG. 4A, the solder pad unit 100a may include a semiconductor layer 110, an electrode 180 electrically connected to the semiconductor layer 110, an electrode pad 120 electrically connected to the electrode 180, an insulating layer 190 configured to insulate a remaining portion other than a portion in which the electrode 180 is electrically connected to the electrode pad 120, a passivation layer 130 configured to insulate a remaining portion other than an exposed portion of the electrode pad 120, a solder bump 160 electrically connected to the electrode pad 120, and a first UBM layer 140 and a second UBM layer 150 configured to electrically connect and physically adhere the electrode pad 120 and the solder bump 160 to each other and reduce a chance of or prevent separation of the solder bump 160.

The first UBM layer 140 may include a first adhesive layer 141, a diffusion barrier layer 142, a first wetting layer 143, and a second adhesive layer 144. The second UBM layer 150 may include a third adhesive layer 151 and a second wetting layer 152. Since structural characteristics of the first and second UBM layers 140 and 150 are described above, detailed descriptions thereof are omitted.

Referring to FIG. 4B, the solder pad unit 100b may further include a first compound layer 145 and a second compound layer 153 in contrast with the solder pad unit 100a of FIG. 4A. The first compound layer 145 may include a first intermetallic compound that is formed due to a chemical reaction of a base material of the first wetting layer 143 with a solder of the solder bump 160. The second compound layer 153 may include a second intermetallic compound that is formed due to a chemical reaction of a base material of the second wetting layer 152 with the solder of the solder bump 160. The first intermetallic compound may be the same material as or a different material from the second intermetallic compound. In other embodiments the first compound layer 145 and the second compound layer 153 may have various positions. Since the positions of the first and second compound layers 145 and 153 are described above, detailed descriptions thereof are omitted.

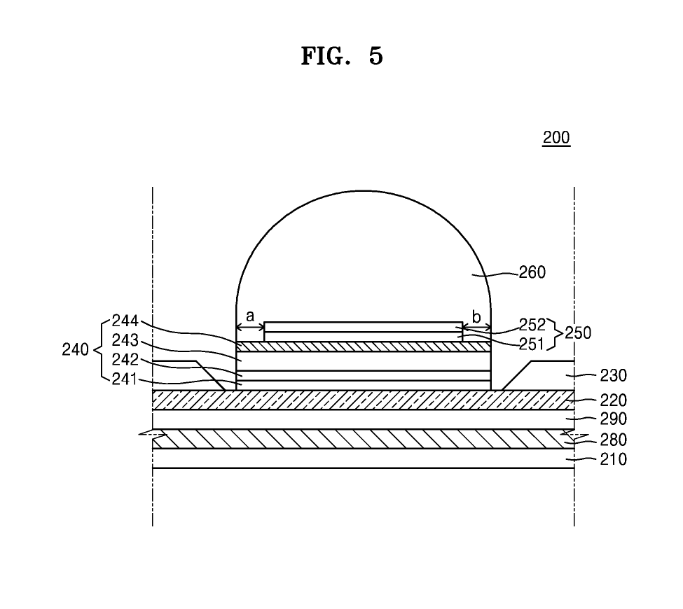

FIG. 5 is a side cross-sectional view of a solder pad unit 200 according to another embodiment. Referring to FIG. 5, a second UBM layer 250 may have a stacked structure different from the second UBM layer 150 of FIG. 4A. The second UBM layer 250 may have a horizontal width that is smaller than a maximum horizontal width of a solder bump 260. The second UBM layer 250 may be formed to have a smaller horizontal width than a first UBM layer 240. That is, the second UBM layer 250 may be formed to have a smaller width than the first UBM layer 240 by as much as a left width ‘a’ and a right width ‘b’. The left width ‘a’ may have the same or a different value from the right width ‘b’. That is, photoresist may be formed on the first UBM layer 240 and patterned to form a photoresist pattern, and the second UBM layer 250 may be formed on a second adhesive layer 244 exposed by the photoresist pattern. In this case, an exposure range of the second adhesive layer 244 exposed by the photoresist pattern may be varied, thereby forming the second UBM layer 250 having a smaller horizontal width than the first UBM layer 240 as shown in FIG. 5. In another case, an insulating layer may be stacked on the first UBM layer 240, and a portion of the insulating layer may be etched in consideration of an exposed region of the first UBM layer 240, and the second UBM layer 250 may be stacked on the etched portion of the insulating layer. Thus, the second UBM layer 250 having a smaller horizontal width than the first UBM layer 240 may be formed. The second UBM layer 250 may be stacked using a sputtering process, a deposition process, a plating process, or the like. The first UBM layer 240 may include a metal seed layer not shown), and the second UBM layer 250 may be a layer grown from the metal seed layer. However, embodiments are not limited thereto, and the second UBM 250 may be stacked on the first UBM layer 240 using various processes. Thus, a solder of the solder bump 260 may be directly adhered to the first UBM layer 240. The solder bump 260 may be formed by forming a first intermetallic compound between a first wetting layer 243 and the solder.

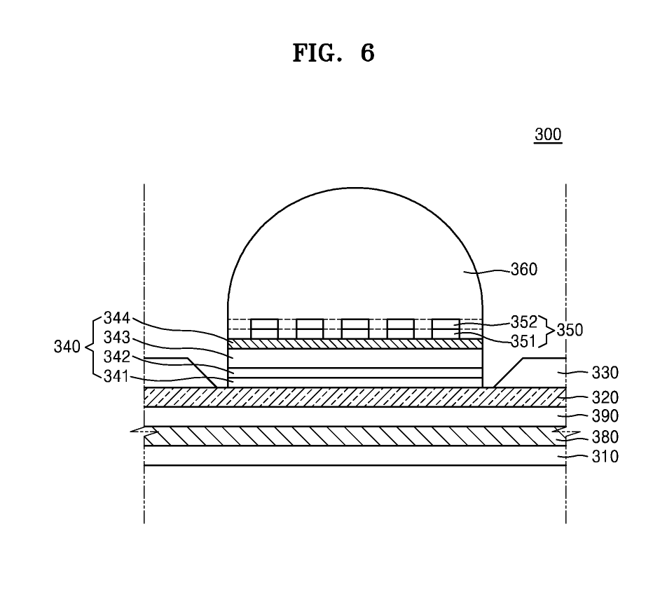

FIG. 6 is a side cross-sectional view of a stacked shape of a second UBM layer 350, according to another embodiment. Referring to FIG. 6, the second UBM layer 350 may have a stacked shape different from the second UBM layer 150 of FIG. 4A. The second UBM layer 350 may be separated into at least two pieces on the first UBM layer 340, and a solder of a solder bump 360 may fill spaces between the separated pieces. In FIG. 6, five pieces of the second UBM layer 350 may be spaced a predetermined distance apart from one another and disposed on the first UBM layer 340. An insulating layer may be stacked on a first UBM layer 340, portions of the insulating layer may be etched in consideration of the stacked shape of the second UBM layer 350, and the second UBM layer 350 may be stacked on the etched portions of the insulating layer. Thus, the second UBM layer 350 of FIG. 6 may be formed. In another case, the second UBM layer 350 may be stacked on the first UBM layer 340, and photoresist may be formed on the second UBM layer 350 and patterned to form a photoresist pattern. Thus, the second UBM layer 350 may be formed in at least two separated pieces.

However, embodiments are not limited to the present embodiment, and the second UBM layer 350 may be formed using various processes. The second UBM layer 350 may be separated into multiple pieces, which are spaced respectively different distances from one another, and stacked on the first UBM layer 340. As a result, the solder of the solder bump 360 may be directly adhered to the first UBM layer 340, and the solder bump 360 may be formed by forming a first intermetallic compound between the first wetting layer 343 and the solder of the solder bump 360.

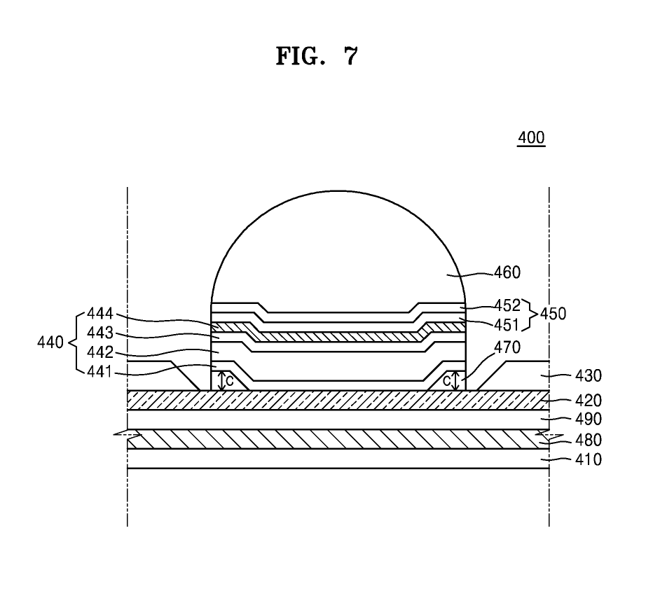

FIG. 7 is a detailed side cross-sectional view of a stacked structure of a solder pad unit 400 according to another embodiment. Referring to FIG. 7, the solder pad unit 400 may be similar to, but further include a buffer layer 470 different from the solder pad unit 100 of FIG. 4A. The buffer layer 470 may be disposed on at least a portion of an electrode pad 420. Accordingly, the buffer layer 470 may act as an electrical insulator and serve to reduce an external impact. In an embodiment, the buffer layer 470 may include at least one of polyimide, epoxy, and silicon oxide. A portion of a first UBM layer 440 may be stacked on the buffer layer 470. A height ‘c’ of the buffer layer 470 may be adjusted during a process of forming the solder pad unit 400. A height of a solder bump 460 may be controlled by adjusting the height ‘c’ of the buffer layer 470.

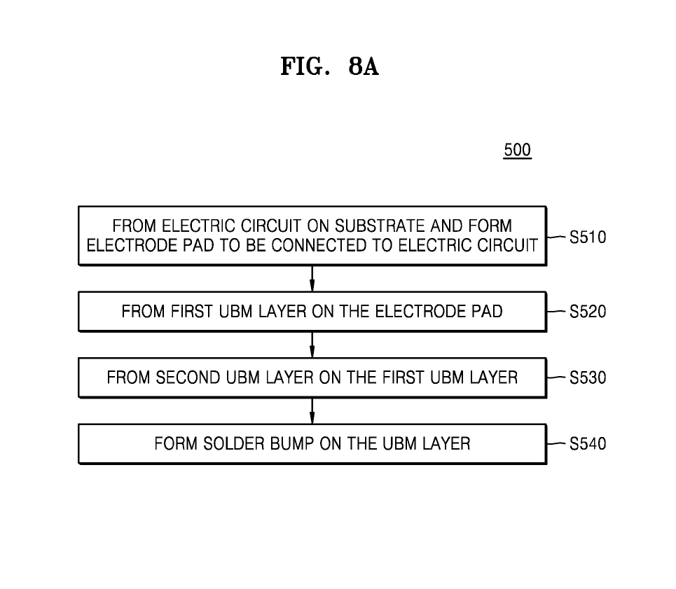

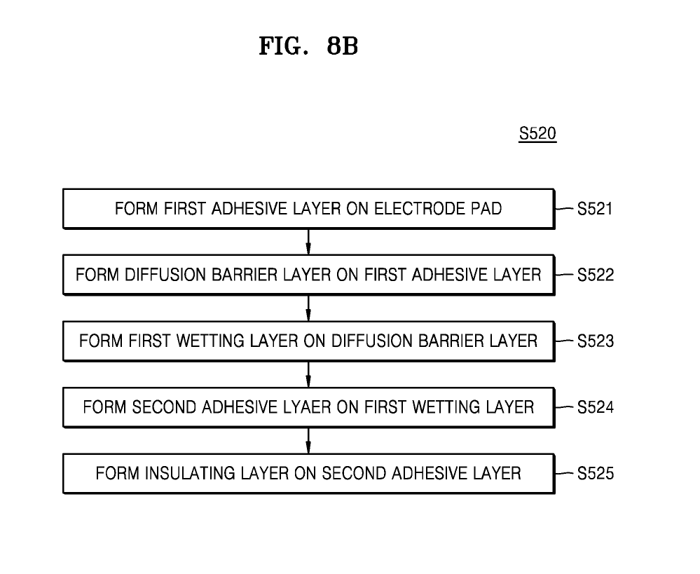

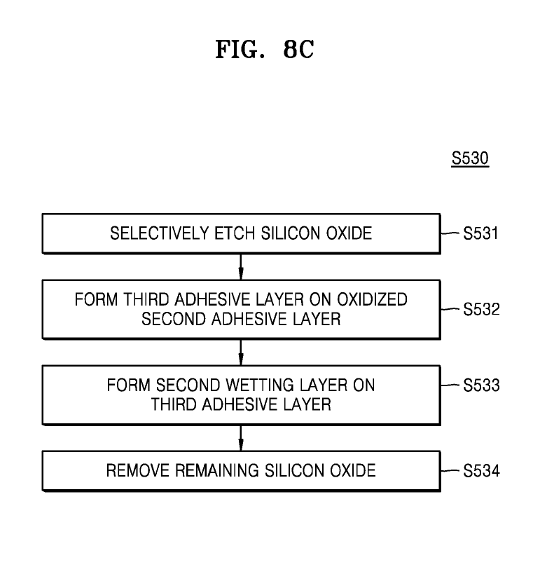

FIGS. 8A, 8B, and 8C are flowcharts illustrating a method 500 of manufacturing a solder pad unit according to an embodiment. Referring to FIG. 8A, an electric circuit may be formed on a substrate and an electrode pad may be formed to be connected to the electric circuit formed on the substrate (S510). Thereafter, a passivation layer including an insulating material, such as silicon oxide, may be stacked on the electrode pad, and a portion of the passivation layer may be removed to expose at least a portion of the electrode pad. Next, a first UBM layer may be formed on the electrode pad exposed by removing the portion of the passivation layer (S520). Thereafter, a partially etched insulating layer or photoresist pattern may be formed on the first UBM layer, and a second UBM layer may be stacked on the first UBM layer (S530). Thereafter, a solder may be formed on the second UBM layer, the etched insulating layer or photoresist pattern may be removed, and a solder bump may be formed by using a solder reflow process (S540). Optionally, the first UBM layer or the second UBM layer may be removed by using an intermetallic compound formed on the first UBM layer or the second UBM layer as a mask to form the solder pad unit.

FIG. 8B is a detailed flowchart of an example of an operation S520 of stacking the first BUM layer of FIG. 8A. Initially, a first adhesive layer may be formed on an electrode pad (S521). Thereafter, a diffusion barrier layer may be formed on the first adhesive layer (S522), and a first wetting layer may be formed on the diffusion barrier layer (S523). Next, a second adhesive layer may be formed on the first wetting layer (S524), and an insulating layer formed of, for example, silicon oxide, may be formed on the second adhesive layer (S525). In another embodiment, a photoresist pattern may be formed on the second adhesive layer.

FIG. 8C is a detailed flowchart of an operation S530 of stacking the second UBM layer of FIG. 8A. An insulating layer formed of, for example, silicon oxide, may be etched to expose a portion of a first UBM layer (S531), and a third adhesive layer may be formed on a second adhesive layer that is oxidized during the etching process (S532). Thereafter, a second wetting layer may be formed on the third adhesive layer (S533). Subsequently, the remaining insulating layer formed of silicon oxide may be removed (S534).

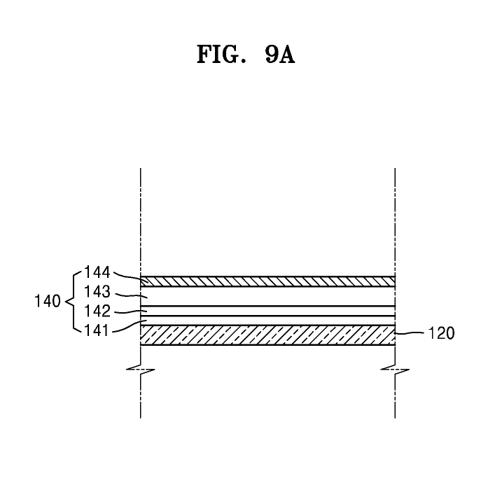

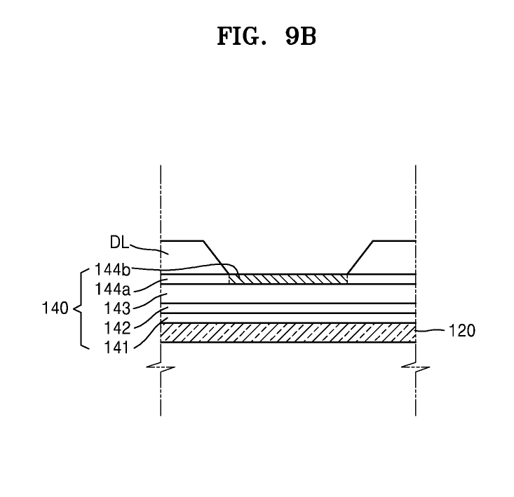

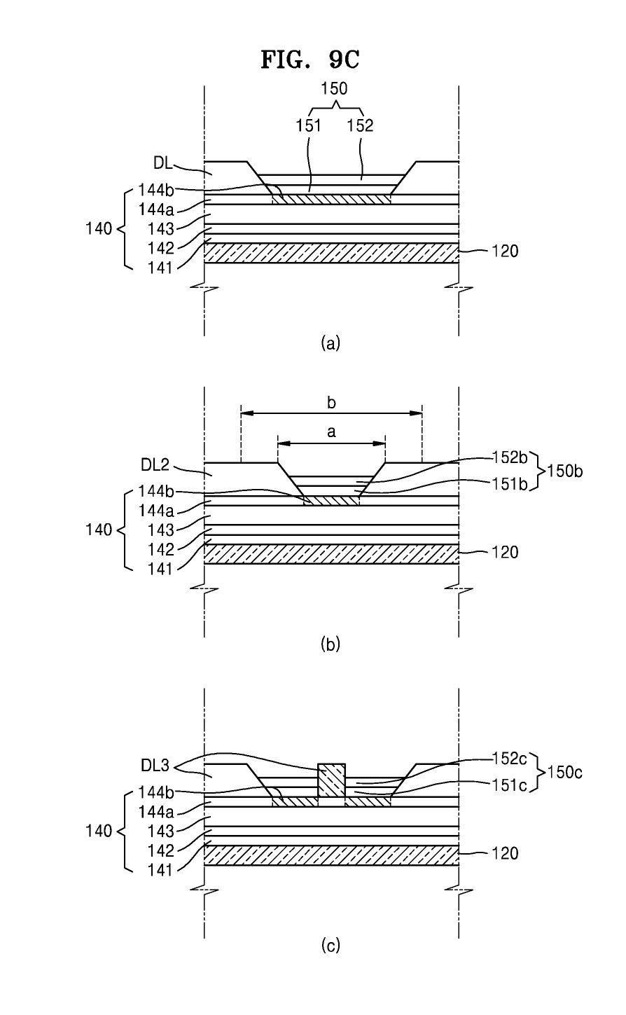

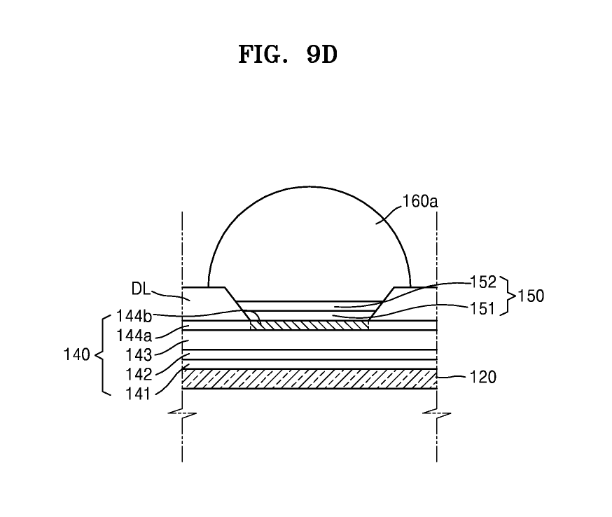

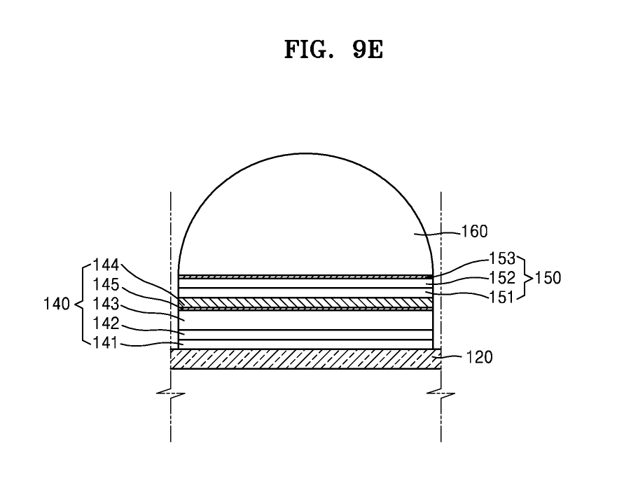

FIGS. 9A to 9E illustrate a method of manufacturing the solder pad unit 100 of FIG. 1C, according to an embodiment. In FIGS. 9A to 9E, descriptions of the semiconductor layer 110, the electrode 180, and the insulating layer 190 of the semiconductor chip 100 of FIG. 1C are omitted.

Referring to FIG. 9A, an electrode pad 120 may be formed to be electrically connected to an electric circuit formed on a substrate. Thereafter, a first adhesive layer 141 may be formed and stacked on the electrode pad 120, and a diffusion barrier layer 142 may be formed and stacked on the first adhesive layer 141. In this case, the first adhesive layer 141 and the diffusion barrier layer 142 may be formed at substantially the same time and include substantially the same material. Thereafter, a first wetting layer 143 may be formed and stacked on the diffusion barrier layer 142, and a second adhesive layer 144 may be formed and stacked on the first wetting layer 143 to improve adhesion of the second adhesive layer 144 with an insulating layer DL to be stacked later. Thus, a first UBM layer 140 may be formed. The first UBM layer 140 may be stacked using a sputtering process or a deposition process or grown from a metal seed layer, but embodiments are not limited thereto.

Referring to FIB. 9B, the insulating layer DL, which is patterned to expose a portion of the first UBM layer 140, may be formed. The insulating layer DL may be, for example, a silicon oxide layer. Optionally, a photoresist pattern may be formed to expose the portion of the first UBM layer 140. In this case, an exposed portion of the second adhesive layer 144 disposed in an upper portion of the first UBM layer 140 may be oxidized to form an adhesive oxide layer 144b, and an unexposed portion 144a of the second adhesive layer 144 may remain unoxidized. In an embodiment, the adhesive oxide layer 144b may be formed to a thickness corresponding to the entire thickness of the second adhesive layer 144 or to a thickness corresponding to a partial thickness thereof.

Referring to (a) of FIG. 9C, a third adhesive layer 151 may be formed on the adhesive oxide layer 144b, and a second wetting layer 152 may be formed on the third adhesive layer 151, thereby forming a second UBM layer 150. The third adhesive layer 151 and the second wetting layer 152 of the second UBM layer 150 may be respectively formed using a sputtering process or a deposition process or grown from a metal seed layer, but embodiments are not limited thereto.

Referring to (b) of FIG. 9C, a second UBM layer 150b having a smaller horizontal width than the first UBM layer 140 may be stacked by controlling an etching region of an insulating layer DL2. That is, the second UBM layer 150b may be stacked by controlling a distance ‘a’ between etched insulating layers DL2 of (b) of FIG. 9C to be smaller than a distance ‘b’ between etched insulating layers DL of (a) of FIG. 9C. The distance ‘a’ between the etched insulating layers DL2 may be smaller than a width of a solder bump to be formed subsequently. However, embodiments are not limited to the present embodiment, and a horizontal width of the second UBM layer 150b may be controlled by pattering photoresist or using various other methods.

Referring to (c) of FIG. 9C, a second UBM layer 150c may be stacked in at least two pieces on a first UBM layer 140. Operations described with reference to (a) of FIG. 9C may be performed so that the second UBM layer 150c may be formed as shown in (c) of FIG. 9C by using an etched insulating layer DL3 formed on the second UBM layer 150c as a mask. In another embodiment, the second UBM layer 150c may be stacked through a photoresist pattern. Subsequently, a hatched portion of the insulating layer DL3 may be selectively removed before a solder is formed. However, embodiments are not limited to the present embodiment, and the second UBM layer 150c may be formed using various processes.

Referring to FIG. 9D, a solder 160a may be formed on the second wetting layer 152 by using a plating process. Thereafter, the insulating layer DL may be removed. The solder 160a may be reflowed, and an intermetallic compound may be formed due to a chemical reaction of the solder 160a with a base material of the first wetting layer 143 and/or a base material of the second wetting layer 152.

Referring to FIG. 9E, the second wetting layer 152 may include a second compound layer 153 formed of a second intermetallic compound, and the first wetting layer 143 may include a first compound layer 145 formed of a first intermetallic compound. Although FIG. 9E illustrates an example in which the second compound layer 153 and the first compound layer 145 are formed on surfaces of the second wetting layer 152 and the first wetting layer 143, respectively, embodiments are not limited thereto, and the second compound layer 153 and the first compound layer 145 may be formed in other positions. Thereafter, the solder bump 160 may form a stable compound in an etchant, and unnecessary portions of the first UBM layer 140 and the second UBM layer 150 may be removed by using the solder bump 160 as a mask. As described above, by further stacking the second UBM layer 150 on the first UBM layer 140, adhesion of the solder pad unit 100 to the solder bump 160 may be improved, and mechanical reliability of a semiconductor chip or a semiconductor apparatus including the solder pad unit 100 may be improved. Although FIG. 9E illustrates an example in which side surfaces of the respective layers are aligned in a vertical direction, the side surfaces of the respective layers may not be aligned in the vertical direction depending on wet etching characteristics.

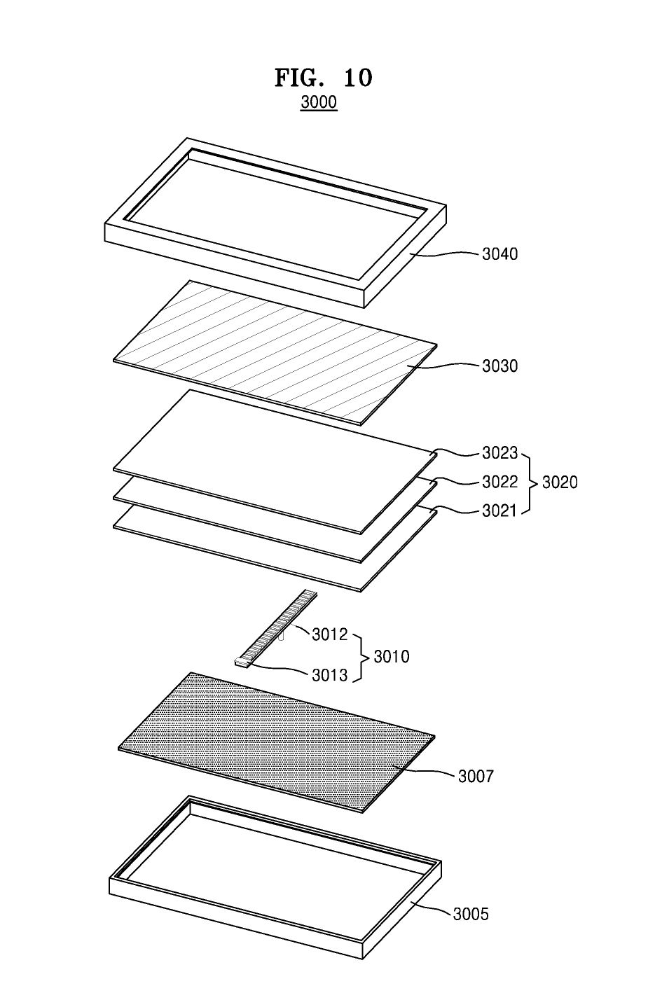

FIG. 10 is an exploded perspective view of a backlight (BL) assembly 3000 including a light-emitting device array unit in which an LED chip manufactured using a method of manufacturing an LED chip, according to an embodiment, is arranged.

As shown in FIG. 10, a direct-light-type BL assembly 3000 may include a lower cover 3005, a reflection sheet 3007, a light-emitting module 3010, an optical sheet 3020, an LC panel 3030, and an upper cover 3040. A light-emitting device array unit, according to an embodiment, may be used as the light-emitting module 3010 included in the direct-light-type BL assembly 3000.

According to an embodiment, the light-emitting module 3010 may include a light-emitting device array 3012 including at least one light-emitting device package and a circuit substrate and a rank storage unit 3013. As in the above-described embodiments, the light-emitting device array 3012 may include a semiconductor chip or light-emitting apparatus including the solder pad unit 100 of FIG. 1. The light-emitting device array 3012 may receive power for emitting light from a light-emitting device driver disposed outside the direct-light-type BL assembly 3000, and the light-emitting device driver may control current supplied to the light-emitting device array 3012.

The optical sheet 3020 may be disposed on the light-emitting module 3010 and include a diffuser sheet 3021, a condensing sheet 3022, and a protection sheet 3023. That is, the diffuser sheet 3021 configured to diffuse light emitted by the light-emitting module 3010, the condensing sheet 3022 configured to condense the light diffused by the diffuser sheet 3021 and increase luminance, and the protection sheet 3023 configured to protect the condensing sheet 3012 and ensure a view angle may be sequentially prepared on the light-emitting module 3010.

The upper cover 3040 may enclose an edge of the optical sheet 3020 and be assembled with the lower cover 3005.

The LC panel 3030 may be further provided between the optical sheet 3020 and the upper cover 3040. The LC panel 3030 may include a pair of a first substrate (not shown) and a second substrate (not shown), which may be bonded to each other with an LC layer therebetween. Multiple gate lines may intersect multiple data lines to define pixel regions on the first substrate. Thin-film transistors (TFTs) may be respectively provided at intersections between the pixel regions, and may correspond one-to-one to and be connected to pixel electrodes mounted on the respective pixel regions. The second substrate may include red (R), green (G), and blue (B) color filters respectively corresponding to the pixel regions and a black matrix covering edges of the respective color filters, the gate lines, the data lines, and the TFTs.

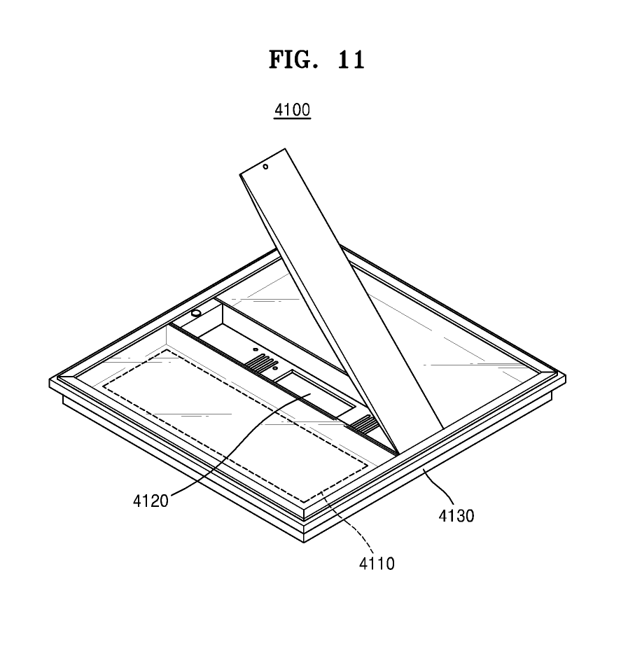

FIG. 11 is a schematic diagram of a flat-panel semiconductor light-emitting apparatus 4100 including a light-emitting device array unit and a light-emitting device module in which an LED chip manufactured using a method of manufacturing an LED chip, according to an embodiment, is arranged.

The flat-panel semiconductor light-emitting apparatus 4100 may include a light source 4110, a power supply device 4120, and a housing 4130. According to an embodiment, the light source 4110 may include a light-emitting device array unit including a light emitting apparatus or semiconductor chip according to an embodiment.

The light source 4110 may include a light-emitting device array unit and have an overall plane shape as shown in FIG. 11.

The power supply device 4120 may be configured to supply power to the light source 4110.

The housing 4130 may include a containing space in which the light source 4110 and the power supply device 4120 are contained, and have a hexahedral shape having one open side surface, but embodiments are not limited thereto. The light source 4110 may be disposed to emit light toward the open side surface of the housing 4130.

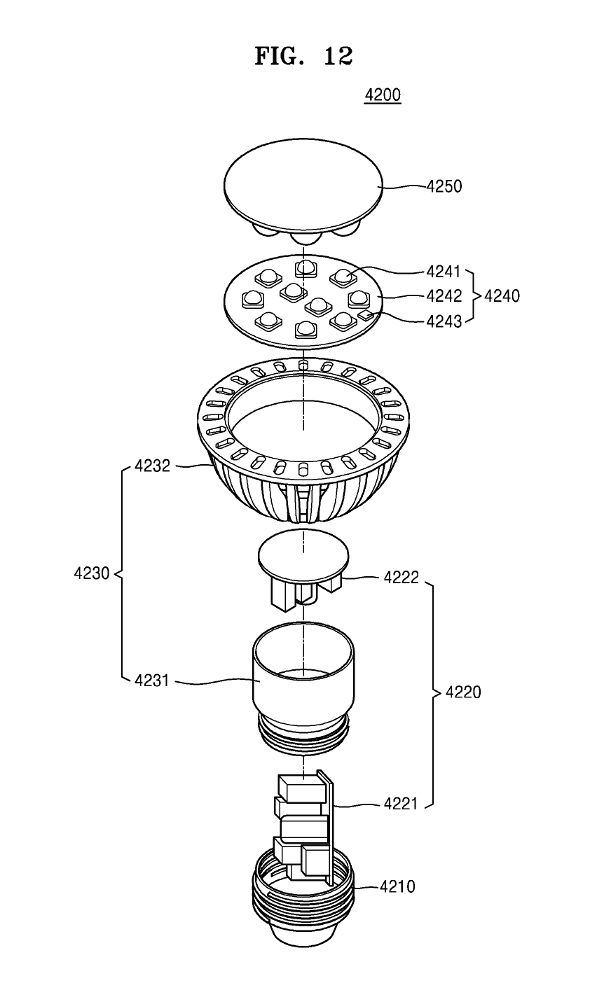

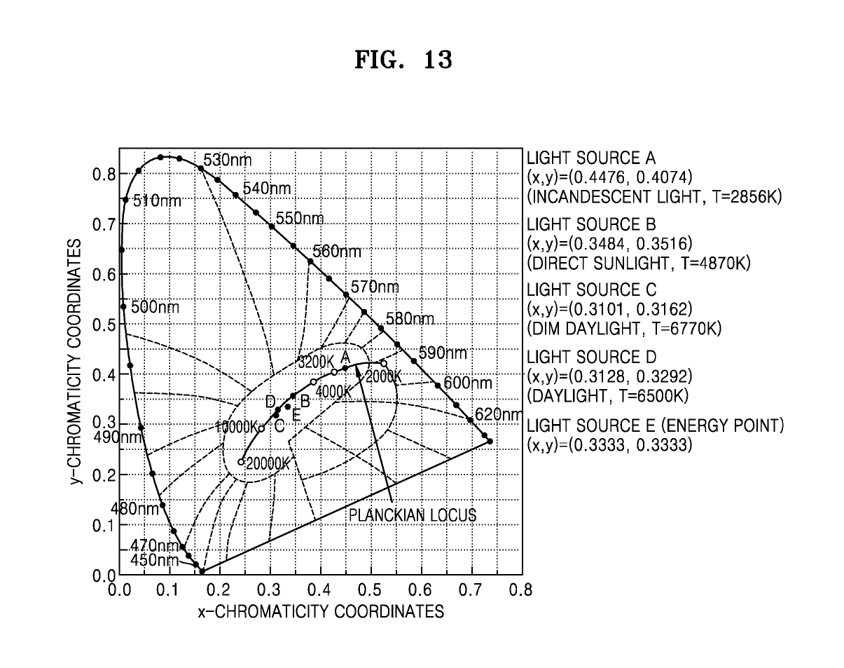

FIG. 12 is a schematic diagram of a bulb-type lamp, which is a semiconductor light-emitting apparatus 4200 including a light-emitting device array unit and a light-emitting device module in which an LED chip manufactured using a method of manufacturing an LED chip, according to an embodiment, is arranged. FIG. 13 is an international commission on illumination (CIE) chromaticity diagram of a complete radiator spectrum. The semiconductor light-emitting apparatus 4200 may include a socket 4210, a power source unit 4220, a heat radiation unit 4230, a light source 4240, and an optical unit 4250. According to an embodiment, the light source 4240 may include a light-emitting device array unit including a light-emitting apparatus or semiconductor chip according to an embodiment.

The socket 4210 may be configured to be capable of being replaced by various standard sockets. Power supplied to the illumination system 4200 may be applied through the socket 4210. As shown in FIG. 12, the power source unit 4220 may be formed by assembling a first power source unit 4221 and a second power source unit 4222.

The heat radiation unit 4230 may include an internal radiation unit 4231 and an external radiation unit 4232. The internal radiation unit 4231 may be directly connected to the light source 4240 and/or the power source unit 4220 so that heat may be transmitted to the external radiation unit 4232. The optical unit 4250 may include an internal optical unit (not shown) and an external optical unit (not shown) and may be configured to substantially uniformly disperse light emitted by the light source 4240.

The light source 4240 may be configured to receive power from the power source unit 4220 and emit light to the optical unit 4250. The light source 4240 may include a light-emitting device array unit, according to one or more of the embodiments. The light source 4240 may include at least one light-emitting device package 4241, a circuit substrate 4242, and a rank storage unit 4243, and the rank storage unit 4243 may store rank information of light-emitting device packages 4241.

Multiple light-emitting device packages 4241 included in the light source 4240 may be of the same kind to generate light having the same wavelength. Alternatively, the light-emitting device packages 4241 included in the light source 4240 may be of different kinds to generate light having different wavelengths. For example, the light-emitting device package 4241 may include a blue light-emitting device, a white light-emitting device manufactured by combining yellow, green, red, or orange phosphors, and at least one of violet, blue, green, red, or infrared (IR) light-emitting devices so as to control a color temperature of white light and a color rendering index (CRI). Alternatively, when an LED chip emits blue light, a light-emitting device package including at least one of yellow, green, and red phosphors may be configured to emit white light having various color temperatures according to a combination ratio of the phosphors. Alternatively, a light-emitting device package in which a green or red phosphor is applied to the blue LED chip may be configured to emit green or red light. The light-emitting device package configured to emit white light may be combined with the light-emitting device package configured to emit green or red light so as to control a color temperature of white light and CRI. Also, the light-emitting device package 4241 may include at least one of light-emitting devices configured to emit violet, blue, green, red, or IR light. In this case, the semiconductor light-emitting apparatus 4200 may be configured to control CRI to the level of about 40 to about 100, and generate various white light beams at a color temperature of about 1500K to about 20000K. When necessary, the semiconductor light-emitting apparatus 4200 may be configured to generate violet, blue, green, red, or orange visible light or IR light and control color of illumination according to an ambient atmosphere or mood. Also, the semiconductor light-emitting apparatus 4200 may be configured to generate light having a specific wavelength to facilitate growth of plants.

White light generated by a combination of the blue light-emitting device with yellow, green, red phosphor and/or green and red light-emitting devices may have at least two peak wavelengths. As shown in FIG. 13, coordinates (x, y) of the white light in a CIE 1931 coordinate system may be located on a segment connecting (0.4476, 0.4074), (0.3484, 0.3516), (0.3101, 0.3162), (0.3128, 0.3292), and (0.3333, 0.3333) or located in a region surrounded with the segment and a blackbody radiator spectrum. A color temperature of the white light may be between 1500K and 20000K.

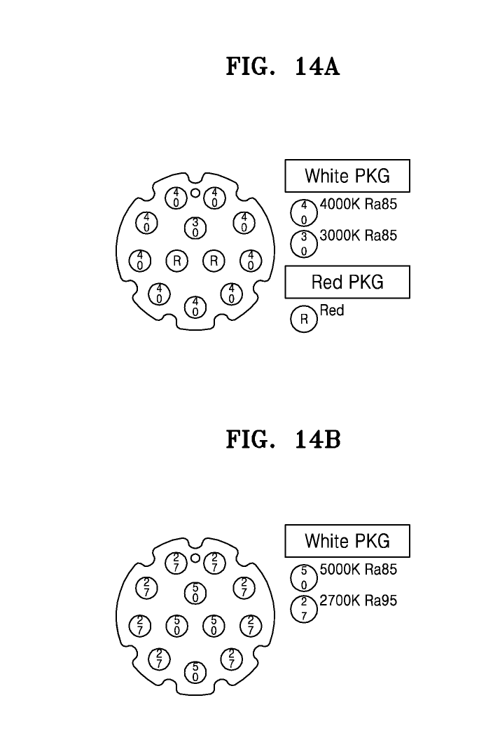

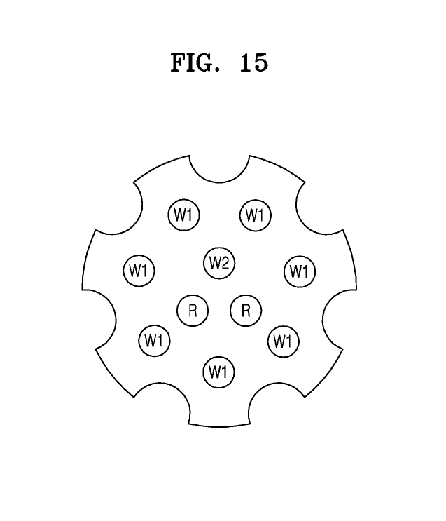

FIGS. 14A and B are each a diagram of an example of a light-emitting device package in which an LED chip manufactured using a method of manufacturing an LED chip, according to an embodiment, is arranged. Referring to FIG. 14A, for example, a white light-emitting package module of which a color temperature may be controlled within a range of about 2000K to about 4000K and CRI (Ra) is about 85 to about 99 may be manufactured by combining a white light-emitting device package having a color temperature of about 4000K and a red light-emitting device package having a color temperature of about 3000K. FIG. 15 illustrates an example of such a light-emitting device package with white light-emitting device packages W1 and W2, and red light-emitting device packages R.

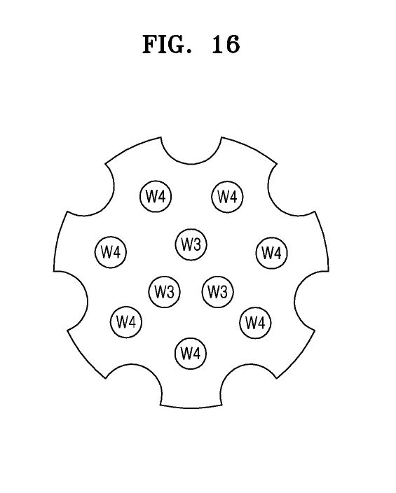

Referring to FIG. 14B, in other embodiments, a white light-emitting package module of which a color temperature may be controlled within a range of about 2700K to about 5000K and CRI (Ra) is about 85 to about 99 may be manufactured by combining a white light-emitting device package having a color temperature of about 2700K and a white light-emitting device package having a color temperature of about 5000K. FIG. 16 illustrates an example of such a light-emitting device package with corresponding white light-emitting device packages W3 and white light-emitting device packages W4.

The number of light-emitting device packages having respective color temperatures may mainly depend on a default color temperature. In an illumination system of which a default color temperature is about 4000K, the number of light-emitting device packages having a color temperature of about 4000K may be set to be larger than the number of light-emitting device packages having a color temperature of about 3000K or the number of red light-emitting device packages.

Phosphors may have formulas and colors as follows.

Oxide-based phosphors: yellow and green Y₃Al₅O₁₂:Ce, Tb₃Al₅O₁₂:Ce, Lu₃Al₅O₁₂:Ce

Silicate-based phosphors: yellow and green (Ba,Sr)₂SiO₄:Eu, yellow and orange (Ba,Sr)₃SiO₅:Ce

Nitride-based phosphors: green β-SiAlON:Eu, yellow La₃Si₆N₁₁:Ce, orange α-SiAlON:Eu, red CaAlSiN₃:Eu, Sr₂Si₅N₈:Eu, SrSiAl₄N₇:Eu, SrLiAl₃N₄:Eu,

Ln₄₋ₓ(Eu_{z}M_{1-z})ₓSi_{12-y}Al_{y}O_{3+x+y}N_{18-x-y}(0.5≦x≦3,0<z<0.3,0<y≦4) Formula (1)

In Formula (1), Ln may be at least one element selected from the group consisting of a Group IIIa element and a rare-earth element, and M may be at least one element selected from the group consisting of calcium (Ca), barium (Ba), strontium (Sr), and magnesium (Mg).

Fluoride-based phosphors: KSF-based red K₂SiF₆:Mn₄+, K₂TiF₆:Mn₄+, NaYF₄:Mn₄+, NaGdF₄:Mn₄+

Compositions of the phosphors should be based on stoichiometry, and respective elements may be replaced by other elements in respective groups in the periodic table. For example, Sr may be replaced by Group II elements (alkaline earths), such as Ba, Ca, or Mg, and Y may be replaced by a lanthanum-based element, such as Tb, Lu, Sc, or Gd. Also, europium (Eu) serving as an activator may be replaced by cerium (Ce), terbium (Tb), praseodymium (Pr), erbium (Er), or ytterbium (Yb) according to a desired energy level. An activator may be used alone or a co-activator may be further applied to vary characteristics.

Furthermore, materials, such as quantum dots (QDs), may be used as materials capable of replacing phosphors, and phosphors and QDs may be used alone or in combination with one another.

A QD may have a structure including a core (about 3 nm to about 10 nm), such as CdSe or InP, a shell (about 0.5 nm to about 2 nm), such as ZnS and ZeSe, and a ligand for stabilizing the core and the shell, and may be embodied in various colors according to size.

Although the present embodiment describes a case in which a wavelength conversion material is contained in an encapsulant, the wavelength conversion material may be bonded as a film type on a top surface of the LED chip or coated to a uniform thickness on the top surface of the LED chip.

The following Table 1 shows types of phosphors in respective fields to which a white light-emitting device using a blue LED chip (about 440 nm to about 460 nm) is applied.

TABLE 1

| Purpose | Phosphor |
|---|---|
| LED TV BLU | β-SiAlON: Eu2+ |
| | (Ca, Sr)AlSiN₃: Eu2+ |
| | La₃Si₆N₁₁: Ce3+ |
| | K₂SiF₆: Mn4+ |
| | SrLiAl3N4: Eu |
| | Ln₄₋ₓ(Eu₂M₁₋ₓ)ₓSi_{12-y}Al_{y}O₃N_{18-x-y} |
| | (0.5 ≦ x ≦ 3, 0 < z < 0.3, 0 < y ≦ 4) |
| | K2TiF6: Mn4+ |
| | NaYF4: Mn4+ |
| | NaGdF4: Mn4+ |
| Illumination | Lu₃Al₅O₁₂: Ce3+ |
| | Ca-α-SiAlON: Eu2+ |
| | La₃Si₆N₁₁: Ce3+ |
| | (Ca, Sr)AlSiN₃: Eu2+ |
| | Y₃Al₅O₁₂: Ce3+ |
| | K₂SiF₆: Mn4+ |
| | SrLiAl3N4: Eu |
| | Ln₄₋ₓ(EuₓM_{1-z}),Si_{12-y}Al_{y}O₃N_{18-x-y} |
| | (0.5 ≦ x ≦ 3, 0 < z < 0.3, 0 < y ≦ 4) |
| | K2TiF6: Mn4+ |
| | NaYF4: Mn4+ |
| | NaGdF4: Mn4+ |
| Side View | Lu₃Al₅O₁₂: Ce3+ |
| (Mobile, Note PC) | Ca-α-SiAlON: Eu2+ |
| | La₃Si₆N₁₁: Ce3+ |
| | (Ca, Sr)AlSiN₃: Eu2+ |
| | Y₃Al₅O₁₂: Ce3+ |
| | (Sr, Ba, Ca, Mg)2SiO4: Eu2+ |
| | K₂SiF₆: Mn4+ |
| | SrLiAl3N4: Eu |
| | Ln₄₋ₓ(Eu₂M_{1-z})ₓSi_{12-y}Al_{y}O_{3+x+y}N_{18-x-y} |
| | (0.5 ≦ x ≦ 3, 0 < z < 0.3, 0 < y ≦ 4) |
| | K2TiF6: Mn4+ |
| | NaYF4: Mn4+ |
| | NaGdF4: Mn4+ |
| Interior | Lu₃Al₅O₁₂: Ce3+ |
| (Head Lamp, etc.) | Ca-α-SiAlON: Eu2+ |
| | La₃Si₆N₁₁: Ce3+ |
| | (Ca, Sr)AlSiN₃: Eu2+ |
| | Y₃Al₅O₁₂: Ce3+ |
| | K₂SiF₆: Mn4+ |
| | SrLiAl3N4: Eu |
| | Ln₄₋ₓ(EuₓM_{1-z}),Si_{12-y}Al_{y}O_{3+x+y}N_{18-x-y} |
| | (0.5 ≦ x ≦ 3, 0 < z < 0.3, 0 < y ≦ 4) |
| | K2TiF6: Mn4+ |
| | NaYF4: Mn4+ |
| | NaGdF4: Mn4+ |

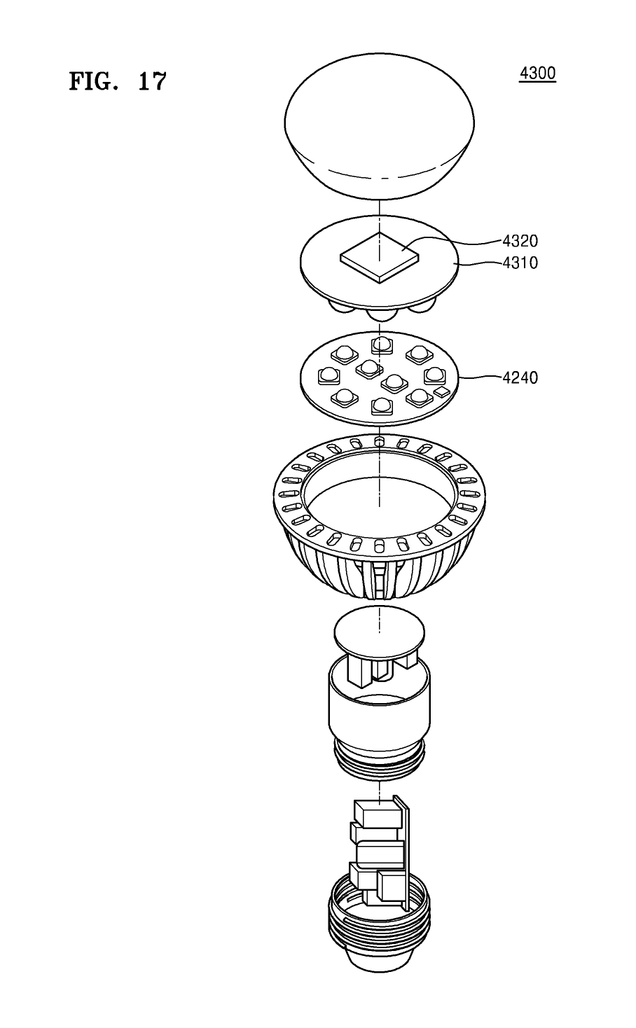

FIG. 17 is a diagram of a lamp 4300 that includes a light-emitting device array unit and a light-emitting device module in which an LED chip manufactured using a method of manufacturing an LED chip, according to an embodiment, is arranged, and includes a communication module 4320. The lamp 4300 of FIG. 15 may differ from the illumination system 4200 of FIG. 12 in that a reflection plate 4310 is disposed on a light source 4240. The reflection plate 4310 may be configured to substantially uniformly disperse light emitted by the light source sideward and backward and reduce light dazzle.

The communication 4320 may be mounted on the reflection plate 4310, and home-network communications may be enabled via the communication module 4320. For example, the communication module 4320 may be a wireless communication module using Zigbee, and be configured to control household illumination (i.e., turning-on/off of a lamp and control of brightness) by means of a smartphone or a wireless controller.

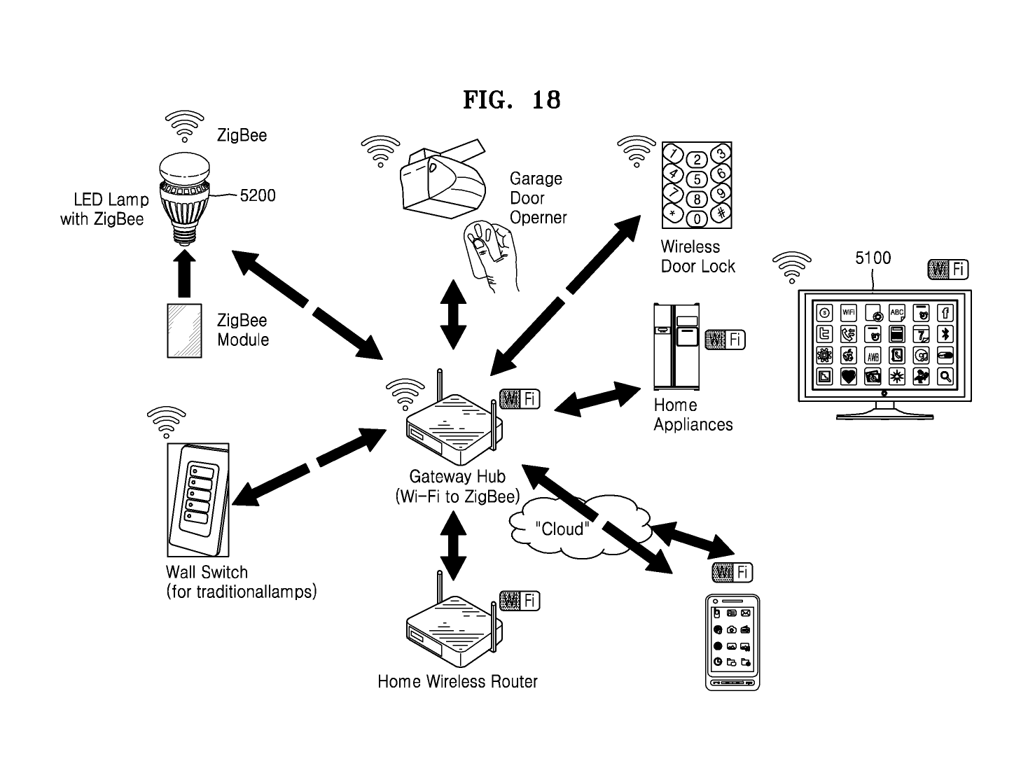

FIG. 18 is a diagram of an example in which a lamp 5200 including a light-emitting device array unit and a light-emitting device module in which an LED chip manufactured using a method of manufacturing an LED chip, according to an embodiment, is arranged, is applied to a home-network. The home-network may be configured to automatically control brightness of the lamp 5200 using household wireless communications (e.g., Zigbee and WiFi) depending on operation states of a bedroom, a living room, a front door, a storage closet, household appliances, garage door openers, door locks, handheld devices, switches, ambient environments and statuses, or the like.

For example, as shown in FIG. 18, the brightness of the lamp 5200 may be automatically controlled depending on the type of a TV program viewed on a TV 5100 or the brightness of a screen of the TV 5100. When a drama is shown on the TV 5100 and a cozy atmosphere is needed, a color temperature of the lamp 5200 may be reduced to about 12000K or lower and the impression of colors may be controlled. In contrast, when a comedy program is shown in a light-hearted atmosphere, a color temperature of the lamp 5200 may be increased to about 12000 K or higher, and the lamp 5200 may be controlled in bluish white colors.

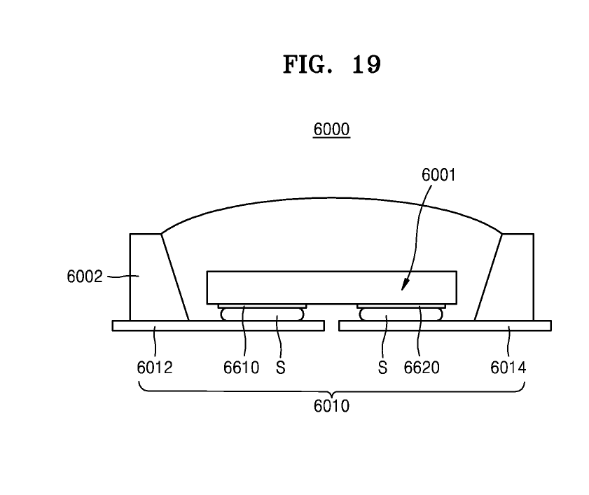

FIG. 19 is a cross-sectional view of an example of a package 6000 to which a semiconductor light-emitting device according to an embodiment is applied. Referring to FIG. 19, a semiconductor light-emitting device package 6000 may include a pair of lead frames 6010 and an encapsulation unit 6005. The semiconductor light-emitting device 6001 may be the semiconductor light-emitting device 1 of FIG. 1 or other embodiments. A first solder pad 6610 and a second solder pad 6620 of the semiconductor light-emitting device 6001 may respectively include the first UBM layer and the second UBM layer described with reference to FIG. 1C or other embodiments, and descriptions thereof are omitted.

The semiconductor light-emitting device 6001 may be mounted on the lead frame 6010, and electrically connected to the lead frame 6010 by a conductive adhesive material. The conductive adhesive material may be, for example, solder bumps S containing tin (Sn) or other conductive material. The pair of lead frames 6010 may include a first lead frame 6012 and a second lead frame 6014. Referring to FIG. 19, the first solder pad 6610 and the second solder pad 6620 of the semiconductor light-emitting device 6001 may be respectively connected to the first lead frame 6012 and the second lead frame 6014 by the solder bumps S interposed between the pair of lead frames 6010.

A package main body 6002 may include a reflection cup to improve light reflection efficiency and light extraction efficiency. The encapsulation unit 6005 formed of a light transmission material may be formed in the reflection cup to encapsulate the semiconductor light-emitting device 6001. The encapsulation unit 6005 may include a wavelength conversion material. Specifically, the encapsulation unit 6005 may include a light-transmitting resin, which may contain at least one of a phosphor that is excited by light emitted by the semiconductor light-emitting device 6001 and emits light having a different wavelength from the light emitted by the semiconductor light-emitting device 6001. Thus, the encapsulant unit 6005 may emit blue light, green light, or red light and be controlled to emit white light or ultraviolet (UV) light.

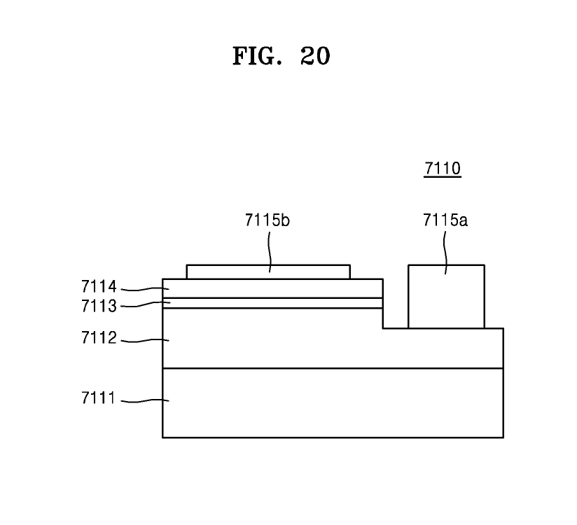

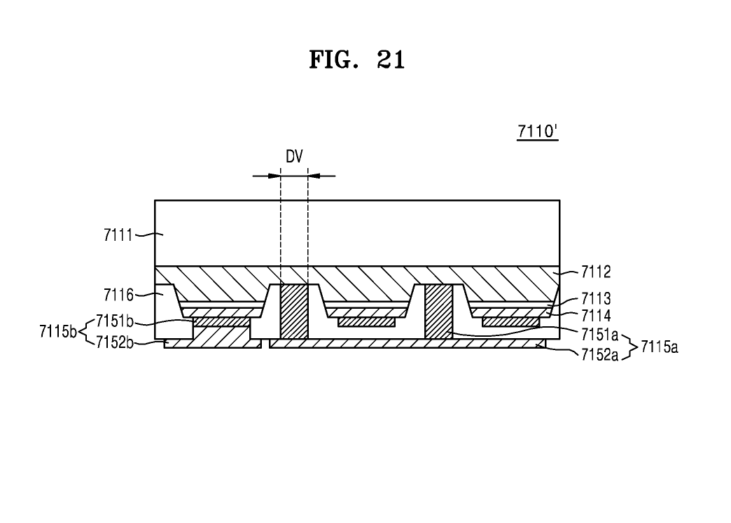

FIGS. 20 and 21 are cross-sectional views of various examples of an LED chip 7110, which may be applied to a light source module, according to an embodiment. Referring to FIG. 20, the LED chip 7110 may include a first-conductivity-type semiconductor layer 7112, an active layer 7113, and a second-conductivity-type semiconductor layer 7114, which may be sequentially stacked on a growth substrate 7111.

The first-conductivity-type semiconductor layer 7112 stacked on the growth substrate 7111 may be an n-type nitride semiconductor layer doped with n-type impurities. Also, the second-conductivity-type semiconductor layer 7114 may be a p-type nitride semiconductor layer doped with p-type impurities. However, in some embodiments, the first and second-conductivity-type semiconductor layers 7112 and 7114 may be stacked in exchanged positions.

The active layer 7113 interposed between the first and second-conductivity-type semiconductor layers 7112 and 7114 may be configured to emit light having predetermined energy due to re-combination between electrons and holes. The active layer 7113 may include a material having a lower energy bandgap than those of the first and second-conductivity-type semiconductor layers 7112 and 7114. The active layer 7113 may have an MQW structure formed by alternately stacking quantum well layers and quantum barrier layers. However, embodiments are not limited thereto, and the active layer 7113 may have an SQW structure, quantum dot, a nanowire, or a nanorod.

The LED chip 7110 may include first and second electrode pads 7115a and 7115b that are electrically connected to the first and second-conductivity-type semiconductor layers 7112 and 7114, respectively. The first and second electrode pads 7115a and 7115b may be exposed and disposed in the same direction. Also, the first and second electrode pads 7115a and 7115b may include a first metal wetting layer and a second metal wetting layer and be electrically connected to a substrate by using a wire bonding technique or a flip-chip bonding technique described with reference to FIG. 1 or other embodiments.

An LED chip 7110′ shown in FIG. 21 may include a semiconductor stacked structure formed on the growth substrate 7111. The semiconductor stacked structure may include a first-conductivity-type semiconductor layer 7112, an active layer 7113, and a second-conductivity-type semiconductor layer 7114.

The LED chip 7110′ may include first and second electrode pads 7115a and 7115b connected to the first and second-conductivity-type semiconductor layers 7112 and 7114, respectively. The first electrode pad 7115a may include conductive vias 7151a, which are connected to the first-conductivity-type semiconductor layer 7112 via the second-conductivity-type semiconductor layer 7114 and the active layer 7113, and an electrode extension unit 7152a connected to the conductive via 7151a. The conductive vias 7151a may be surrounded by an insulating layer 7116 and electrically isolated from the active layer 7113 and the second-conductivity-type semiconductor layer 7114. The conductive vias 7151a may be disposed in an etched region of the semiconductor stacked structure. The number, shape, and pitch of the conductive vias 7151a or contact areas between the conductive vias 7151a and the first-conductivity-type semiconductor layer 7112 may be appropriately adjusted to reduce contact resistances of the conductive vias 7151a. In FIG. 21, DV denotes a diameter of the conductive via 7151a that is in contact with the first-conductivity-type semiconductor layer 7112. Also, the conductive vias 7151a may be arranged in rows and columns on the semiconductor stacked structure to improve the flow of current. The second electrode pad 7115b may include an ohmic contact layer 7151b and an electrode extension unit 7152b disposed on the second-conductivity-type semiconductor layer 7114.

The number of the conductive vias 7151a arranged in rows and columns and the contact areas between the conductive vias 7151a and the first-conductivity-type semiconductor layer 7112 may be adjusted such that an area occupied by the conductive vias 7151a on a plane surface of a region where the conductive vias 7151a are in contact with the first-conductivity-type semiconductor layer 7112 ranges from about 0.5% of the entire area of a plane surface of the semiconductor stacked structure to about 20% thereof. A diameter of the conductive vias 7151a may range from, for example, about 5 μm to about 50 μm in the region where the conductive vias 7151a are in contact with the first-conductivity-type semiconductor layer 7112. Also, the number of the conductive vias 7151a per semiconductor stacked structure may range from about 3 to about 300 according to the area of the semiconductor stacked structure. Although depending on the area of the semiconductor stacked structure, the number of the conductive vias 7151a may be at least 4. The conductive vias 7151a may be arranged in a matrix shape and spaced apart from one another by a distance of about 100 μm to about 500 μm, more preferably, about 150 μm to about 450 μm. When the distance between the conductive vias 7151a is less than about 100 μm, the number of the conductive vias 7151a may increase, and an emission area may be relatively reduced to degrade luminous efficiency. In contrast, when the distance between the conductive vias 7151a is more than about 500 μm, current diffusion may be precluded to degrade luminous efficiency. A depth of the conductive vias 7151a may depend on the thicknesses of the second-conductivity-type semiconductor layer 7114 and the active layer 7113 and range from, for example, about 0.5 μm to about 5.0 μm.

Embodiments include a semiconductor light-emitting device and a semiconductor light-emitting apparatus including the same, which may increase adhesion of an under-barrier metal (UBM) layer with solder bumps and improve reliability between chips or apparatuses.

An embodiment includes a semiconductor light-emitting device including an electrode pad electrically connected to an electrode, a first UBM layer stacked on and adhered to the electrode pad, a second UBM layer stacked on the first UBM layer and having a thin multilayered structure including at least two layers, and a solder bump disposed on the second UBM layer. Adhesion between the second UBM layer and the solder bump may be higher than adhesion between the first UBM layer and the solder bump.

The first UBM layer may include a first adhesive layer stacked on and adhered to the electrode pad, a diffusion barrier layer stacked on the first adhesive layer, and a first wetting layer stacked on the first adhesive layer and configured to react with a solder of the solder bump to form a first intermetallic compound.

The first UBM layer may include a second adhesive layer stacked on the first wetting layer. The second adhesive layer may be selected such that adhesion between the second adhesive layer and an insulating layer is higher than adhesion between the first wetting layer and the insulating layer.

The second adhesive layer may further include an adhesive oxide layer.

The first adhesive layer and the diffusion barrier layer may be formed of the same material.

The first adhesive layer and the diffusion barrier layer may be formed using different processes. A height of the first adhesive layer may be greater than a height of the diffusion barrier layer.

The first wetting layer may include a first compound layer formed of the first intermetallic compound formed due to a reaction of a base material of the first wetting layer with the solder of the solder bump.

The second UBM layer may include a third adhesive layer stacked on and adhered to an upper layer of the first UBM layer, and a second wetting layer configured to react with the solder of the solder bump to form a second intermetallic compound.

An upper layer of the first UBM layer may further include an adhesive oxide layer. The third adhesive layer may be selected such that adhesion between the third adhesive layer and the adhesive oxide layer is higher than adhesion between the second wetting layer and the adhesive oxide layer.

The second wetting layer may include a second compound formed of the second intermetallic compound formed due to a reaction of a base material of the second wetting layer with the solder of the solder bump.

The first UBM layer may have a larger horizontal width than the second UBM layer.

The second UBM layer may be separated into at least two pieces on the first UBM layer, and portions of the solder of the solder bump may be disposed between the separated pieces.

A maximum horizontal width of the solder bump may be greater than a horizontal width of the second UBM layer.

Another embodiment includes a semiconductor light-emitting apparatus comprising a solder bump. The apparatus may include an electric circuit, a first UBM layer configured to electrically connect the solder bump with an electrode pad that is connected to the electric circuit, and a second UBM layer stacked on the first UBM layer to improve adhesion of the first UBM layer with the solder bump.

The second UBM layer may be separated into at least two pieces on the first UBM layer, and portions of the solder of the solder bump may be disposed between the separated at least two pieces.

While embodiments has been particularly shown and described with reference to particular embodiments, it will be understood that various changes in form and details may be made therein without departing from the spirit and scope of the following claims.

1. A semiconductor light-emitting device comprising:
an electrode pad;
a first under-barrier metal (UBM) layer stacked on the electrode pad;
a second UBM layer stacked on the first UBM layer and having a multilayered structure including at least two layers; and
a solder bump disposed on the second UBM layer,
wherein adhesion between the second UBM layer and the first UBM layer is higher than adhesion between the first UBM layer and the solder bump.

2. The device of claim 1, wherein the first UBM layer includes a multilayered structure.

3. The device of claim 1, wherein the first UBM layer comprises:
a first adhesive layer stacked on the electrode pad;
a diffusion barrier layer stacked on the first adhesive layer; and
a first wetting layer stacked on the first adhesive layer.

4. The device of claim 3, wherein the first wetting layer is configured to react with a solder of the solder bump to form a first intermetallic compound.

5. The device of claim 3, wherein the first UBM layer comprises a second adhesive layer stacked on the first wetting layer, and
the second adhesive layer has an adhesion between the second adhesive layer and an insulating layer that is higher than adhesion between the first wetting layer and the insulating layer.

6. The device of claim 5, wherein the second adhesive layer further comprises an adhesive oxide layer.

7. The device of claim 3, wherein the first adhesive layer and the diffusion barrier layer are formed of substantially the same material.

8. The device of claim 3, wherein a height of the first adhesive layer is greater than a height of the diffusion barrier layer.

9. The device of claim 3, wherein the first wetting layer comprises a first compound layer formed of a first intermetallic compound formed due to a reaction of a base material of the first wetting layer with solder of the solder bump.

10. The device of claim 1, wherein the second UBM layer comprises:
a second adhesive layer stacked on and adhered to an upper layer of the first UBM layer; and
a second wetting layer configured to react with the solder of the solder bump to form an intermetallic compound.

11. The device of claim 10, wherein an upper layer of the first UBM layer further comprises an adhesive oxide layer, and
the second adhesive layer has an adhesion between the second adhesive layer and the adhesive oxide layer is higher than adhesion between the second wetting layer and the adhesive oxide layer.

12. The device of claim 10, wherein the second wetting layer comprises a compound formed of an intermetallic compound formed due to a reaction of a base material of the second wetting layer with a solder of the solder bump.

13. The device of claim 1, wherein the first UBM layer has a larger horizontal width than the second UBM layer.

14. The device of claim 1, wherein the second UBM layer is separated into at least two pieces on the first UBM layer, and portions of the solder of the solder bump are disposed between the separated pieces.

15. The device of claim 1, wherein a maximum horizontal width of the solder bump is greater than a horizontal width of the second UBM layer.

16. The device of claim 1, further comprising a buffer layer disposed between the electrode pad and the first UBM layer.

17. A semiconductor light-emitting apparatus comprising a solder bump, the apparatus comprising:
an electric circuit;
a first under-barrier metal (UBM) layer configured to electrically connect the solder bump with an electrode pad that is connected to the electric circuit; and
a second UBM layer stacked on the first UBM layer and configured to increase adhesion of the first UBM layer with the solder bump.

18. The apparatus of claim 17, wherein the second UBM layer is separated into at least two pieces on the first UBM layer, and portions of the solder of the solder bump are disposed between the separated at least two pieces.

19. A semiconductor light-emitting device comprising:
an electrode pad;
a first adhesive layer stacked on the electrode pad;
a diffusion barrier layer stacked on the first adhesive layer;
a first wetting layer stacked on the diffusion barrier layer;
a second adhesive layer stacked on the first wetting layer;
a third adhesive layer stacked on the second adhesive layer;
a second wetting layer stacked on the third adhesive layer; and
a solder bump formed on the second wetting layer.

20. The device of claim 19, further comprising:
a first compound layer disposed between the first wetting layer and the second adhesive layer; and
a second compound layer disposed between the third adhesive layer and the second wetting layer.
